(19) United States
(12) Patent Application Publication
(10) Pub. No.: US 2026/0334044 A1
(43) Pub. Date: Oct. 22, 2026

(54) DISPLAY DEVICE AND ELECTRONIC DEVICE COMPRISING THE SAME

(71) Applicant: SAMSUNG DISPLAY CO., LTD., YONGIN-SI (KR)

(72) Inventors: Eun Kyoung NAM, Yongin-si (KR); Byeong Hee WON, Yongin-si (KR); Hyun Jin CHO, Yongin-si (KR)

(21) Appl. No.: 19/459,116

(22) Filed: Jan. 26, 2026

(30) Foreign Application Priority Data
Apr. 22, 2025 (KR) 10-2025-0052017

(51) Int. Cl. H10K 59/50; H10K 59/127; H10K 59/80

(52) U.S. Cl. CPC H10K 59/50; H10K 59/127; H10K 59/879; H10K 59/8791

(57) ABSTRACT

A display device includes a display panel. A first base substrate is arranged on the display panel. A second base substrate is arranged on the first base substrate. A plurality of lenses is disposed between the first base substrate and the second base substrate. The plurality of lenses comprises liquid crystal molecules having a long-axis and a short-axis and spaced apart from one another with a boundary therebetween. The boundary extends in a longitudinal direction. The liquid crystal molecules are oriented in a long-axis direction of the liquid crystal molecules. An angle formed by the longitudinal direction of the boundary and the long-axis direction of the liquid crystal molecules is in a range of 0 degrees to about 45 degrees.

This application claims priority under 35 U.S.C. §119 to Korean Patent Application No. 10-2025-0052017, filed on Apr. 22, 2025 in the Korean Intellectual Property Office, the disclosure of which is incorporated by reference in its entirety herein.

### 1. TECHNICAL FIELD

The present disclosure relates to a display device and an electronic device including the same.

### 2. DISCUSSION OF RELATED ART

As communication technology and media evolve, display devices are being used to display images in an increasing variety of places and environments. For example, a variety of types of display devices, such as liquid-crystal display (LCD) devices and organic light-emitting display (OLED) devices are widely used and are applied to an increasing number of different electronic devices.

Recently, a three-dimensional (3D) image display device has been developed, which provides divided images of the display device in the space in front of the display device using a lens array. A three-dimensional image display device utilizes a stereoscopic technique that separately displays a left-eye image and a right-eye image to provide a viewer 3D experiences, and a light-field technology that converges light output from each lens of a lens array in a display device onto a viewing area where a viewer observes the display device. Accordingly, research is being actively conducted concerning a light-field 3D display device that increases the number of view areas to display a greater number of stereoscopic three-dimensional images.

### SUMMARY

Aspects of the present disclosure provide a display device with increased display quality.

It should be noted that objects of the present disclosure are not limited to the above-described objects, and other objects of the present disclosure will be apparent to those skilled in the art from the following descriptions.

According to an embodiment of the present disclosure, a display device includes a display panel. A first base substrate is arranged on the display panel. A second base substrate is arranged on the first base substrate. A plurality of lenses is disposed between the first base substrate and the second base substrate. The plurality of lenses comprises liquid crystal molecules having a long-axis and a short-axis and spaced apart from one another with a boundary therebetween. The boundary extends in a longitudinal direction. The liquid crystal molecules are oriented in a long-axis direction of the liquid crystal molecules. An angle formed by the longitudinal direction of the boundary and the long-axis direction of the liquid crystal molecules is in a range from 0 degrees to about 45 degrees.

According to various embodiments of the present disclosure, the angle formed by the longitudinal direction of the boundary and the long-axis direction of the liquid crystal molecules may be in a range of 0 degrees to about 45 degrees.

According to various embodiments of the present disclosure, the angle formed by the longitudinal direction of the boundary and the long-axis direction of the liquid crystal molecules may be 0 degrees.

According to various embodiments of the present disclosure, the display device may further include a polarizing member disposed between the display panel and the first base substrate. The polarizing member transmits light having a first polarization axis. Light incident from the display panel to the first base substrate when a three-dimensional image is generated may have the first polarization axis. An angle formed by the long-axis direction of the liquid crystal molecules and a linear polarization direction by the first polarization axis may be in a range of 0 degrees to about 45 degrees.

According to various embodiments of the present disclosure, as the angle formed by the longitudinal direction of the boundary and the long-axis direction of the liquid crystal molecules decreases, a cross-sectional area of the liquid crystal molecules in a cross-section of the lens taken from the longitudinal direction of the boundary may decrease.

According to various embodiments of the present disclosure, the display device may further include a filler layer disposed between the first base substrate and the second base substrate and having a surface in direct contact with the lens, and a polarizing member disposed between the display panel and the first base substrate and transmitting light having a first polarization axis. A difference between a refractive index of the plurality of lenses and a refractive index of the filler layer at a portion of the surface overlapping a center of a lens of the plurality of lenses may be a first effective refractive index, and a difference between a refractive index of the plurality of lenses and a refractive index of the filler layer at a portion of the surface overlapping a side surface of the lens may be a second effective refractive index. As the angle formed by the longitudinal direction of the boundary and the long-axis direction of the liquid crystal molecules increases, a difference between the first effective refractive index and the second effective refractive index may increase.

According to various embodiments of the present disclosure, as the second effective refractive index decreases, a refraction angle of light passing through the surface including the side surface of the lens may decrease.

According to various embodiments of the present disclosure, the first effective refractive index may be greater than the second effective refractive index.

According to various embodiments of the present disclosure, as the cross-sectional area of the liquid crystal molecules observed when a cross-section of the lens is viewed in the longitudinal direction of the boundary decreases, the second effective refractive index may increase.

According to various embodiments of the present disclosure, as the cross-sectional area of the liquid crystal molecules in a cross-section of the lens taken in the longitudinal direction of the boundary decreases, a difference between the first effective refractive index and the second effective refractive index may decrease.

According to various embodiments of the present disclosure, light incident from the display panel to the first base substrate may have a second polarization axis when a two-dimensional image is generated, and a linear polarization direction by the first polarization axis may be different from a linear polarization direction by the second polarization axis.

According to various embodiments of the present disclosure, an angle formed by a short-axis direction of the liquid crystal molecules and the linear polarization direction by the second polarization axis may be 0 degrees.

According to various embodiments of the present disclosure, the display device may further include a third base substrate disposed between the polarizing member and the first base substrate, a fourth base substrate disposed between the third base substrate and the first base substrate, and driving liquid crystals disposed between the third base substrate and the fourth base substrate. Light incident from the display panel to the driving liquid crystals may have the first polarization axis, and light incident from the driving liquid crystals to the third base substrate when the two-dimensional image is generated may have the second polarization axis.

According to various embodiments of the present disclosure, a linear polarization direction by the first polarization axis may form an acute angle or an obtuse angle with a linear polarization direction by the second polarization axis.

According to various embodiments of the present disclosure, the display device may further include a first driving electrode disposed between the driving liquid crystals and the fourth base substrate, and a second driving electrode disposed between the third base substrate and the driving liquid crystals.

According to various embodiments of the present disclosure, an electronic device may include a processor configured to provide an image signal, a display module configured to receive the image signal from the processor to display an image, and a power module configured to supply power to the display module. The display module may include a display panel, a first base substrate arranged on the display panel, a second base substrate arranged on the first base substrate, and a plurality of lenses disposed between the first base substrate and the second base substrate, comprising liquid crystal molecules having a long-axis and a short-axis, the plurality of lenses is spaced apart from one another with a boundary therebetween. The boundary may extend in a longitudinal direction, the liquid crystal molecules may be oriented in a long-axis direction of the liquid crystal molecules, and an angle formed by the longitudinal direction of the boundary and the long-axis direction of the liquid crystal molecules may be in a range from 0 degrees to about 45 degrees.

According to various embodiments of the present disclosure, the angle formed by the longitudinal direction of the boundary and the long-axis direction of the liquid crystal molecules may be in a range of 0 degrees to about 45 degrees.

According to various embodiments of the present disclosure, the display device may further include a polarizing member disposed between the display panel and the first base substrate and transmitting light having a first polarization axis. Light incident from the display panel to the first base substrate when a three-dimensional image is generated may have the first polarization axis, and an angle formed by the long-axis direction of the liquid crystal molecules and a linear polarization direction by the first polarization axis may be in a range of 0 degrees to about 45 degrees.

According to various embodiments of the present disclosure, as the angle formed by the longitudinal direction of the boundary and the long-axis direction of the liquid crystal molecules decreases, a cross-sectional area of the liquid crystal molecules in a cross-section of the plurality of lenses taken in the longitudinal direction of the boundary may decrease.

According to various embodiments of the present disclosure, light incident from the display panel to the first base substrate when a two-dimensional image is generated may have a second polarization axis, and a linear polarization direction by the first polarization axis may form an acute angle or an obtuse angle with a linear polarization direction by the second polarization axis.

According to an embodiment of the present disclosure, there is provided a means for addressing the problem of uneven display quality caused by the tilt of lenses. For example, the problem of uneven display quality depending on the position of the lenses can be resolved by considering the longitudinal direction of the boundary of the lenses, the orientation of liquid crystals included in the lenses, and the linear polarization direction due to the polarization axis of light incident on the lenses.

According to embodiments of the present disclosure, the cross-sectional area of liquid crystal molecules is formed relatively small when a three-dimensional image is provided, so that image luminance can be increased and light leakage can be prevented. As a result, the display quality of the display device can be increased.

According to an embodiment of the present disclosure, to create a two-dimensional image when the linear polarization direction of outgoing light is changed, the linear polarization direction of the outgoing light forms an acute or obtuse angle with the linear polarization direction of incoming light according to the changed cross-sectional area of the liquid crystal molecules, thereby suppressing image distortion or light leakage of the display device.

### BRIEF DESCRIPTION OF THE DRAWINGS

The above and other aspects and features of the present disclosure will become more apparent by describing in detail embodiments thereof with reference to the attached drawings, in which:

FIG. 1 is an exploded, perspective view showing a display device according to an embodiment of the present disclosure.

FIG. 2 is a perspective view of the display device of FIG. 1.

FIG. 3 is a cross-sectional view showing a part of a display device including emission areas.

FIG. 4 is a cross-sectional view showing an always-refracting light field display device.

FIG. 5 is a cross-sectional view showing a first-type light field display device in which a two-dimensional image is generated.

FIG. 6 is a cross-sectional view showing a first-type light field display device in which a three-dimensional image is generated.

FIG. 7 is a cross-sectional view showing a second-type light field display device in which a two-dimensional image is generated.

FIG. 8 is a cross-sectional view showing a second-type light field display device in which a three-dimensional image is generated.

FIG. 9 is a plan view showing a display panel.

FIG. 10 is a view showing a moiré pattern that occurs due to the optical lens unit placed on the display panel.

FIG. 11 is a view showing tilting an optical lens unit located on a display panel to prevent a moiré pattern.

FIG. 12 is a view showing a display device according to an embodiment of the present disclosure and polarization directions of lights in the display device, etc.

FIG. 13 is a plan view showing the longitudinal direction of the boundary and the orientation of liquid crystal molecules in the display device according to an embodiment of the present disclosure.

FIG. 14 is a cross-sectional view taken along line N – N' of FIG. 13 when a three-dimensional image is generated.

FIG. 15 is a plan view showing the longitudinal direction of the boundary and the orientation of liquid crystal molecules in the display device according to an embodiment of the present disclosure.

FIG. 16 is a cross-sectional view taken along line R – R' of FIG. 15 when a three-dimensional image is generated.

FIG. 17 is a plan view showing the longitudinal direction of the boundary and the alignment direction of liquid crystal molecules in a display device according to Comparative Example 1.

FIG. 18 is a cross-sectional view taken along line T1 – T1' of FIG. 17 when a three-dimensional image is generated.

FIG. 19 is a view showing a display device according to Comparative Example 1 and polarization directions of lights in the display device, etc.

FIG. 20 is a plan view showing the longitudinal direction of the boundary and the orientation of liquid crystal molecules in the display device according to an embodiment of the present disclosure.

FIG. 21 is a cross-sectional view taken along line T2 – T2' of FIG. 20 when a three-dimensional image is generated.

FIG. 22 is a view showing a display device according to the third embodiment of the present disclosure and polarization directions of lights in the display device, etc.

FIG. 23 is a view showing a display device according to an embodiment of the present disclosure and polarization directions of lights in the display device, etc.

FIG. 24 is a cross-sectional view taken along line N – N' of FIG. 13 when a two-dimensional image is generated.

FIG. 25 is a cross-sectional view taken along line T2 – T2' of FIG. 20 when a two-dimensional image is generated.

FIG. 26 is a view for illustrating by comparison the longitudinal direction of the boundary, the polarization direction of light, the alignment direction of liquid crystal molecules, etc. in the display device according to Comparative Example 2.

FIG. 27 is a view for illustrating by comparison the longitudinal direction of the boundary, the polarization direction of light, the alignment direction of liquid crystal molecules, etc. in the display device according to an embodiment of the present disclosure.

FIG. 28 is a block diagram of an electronic device according to an embodiment of the present disclosure.

FIG. 29 is a view showing electronic devices according to a variety of embodiments of the present disclosure.

### DETAILED DESCRIPTION OF EMBODIMENTS

Hereinafter, embodiments of the present disclosure will be described in detail with reference to the accompanying drawings.

The advantages and features of embodiments disclosed herein, and methods of achieving them, will become apparent upon reference to embodiments described in detail with accompanying drawings. However, the invention according to the present disclosure is not limited to the described embodiments, but may be embodied in many different forms.

References to an element or layer as being “on” another element or layer include both cases in which another layer or element is directly on top of or interposed between other elements. When an element or layer as referred to as being “directly on” another element or layer, no intervening elements may be present. Throughout this specification, like reference numerals refer to like components. The shapes, sizes, proportions, angles, numbers, etc. disclosed in the drawings to illustrate embodiments are examples and embodiments of the present disclosure are not necessarily limited thereto.

Although first, second, and the like are used to describe various components, the components are not necessarily limited by these terms. Thus, a first component referred to herein may also be a second component within the technical idea of the present invention.

Each of the features of the various embodiments disclosed herein may be combined or combinable with each other, in part or in whole, and may be technically interlocked and operated in a variety of ways, and each embodiment may be practiced independently of or in conjunction with one another.

Specific embodiments will be described below with reference to the accompanying drawings. Configurations that function substantially the same between embodiments are given the same drawing designation and repeated description may be omitted for economy of explanation.

A display device includes a display panel having a plurality of lenses arranged between first and second base substrates. The plurality of lenses includes liquid crystal molecules. A boundary between adjacent lenses may be arranged to extend in a longitudinal direction. The liquid crystal molecules may be oriented in a long-axis direction of the liquid crystal molecules, and an angle formed by the longitudinal direction of the boundary and the long-axis direction of the liquid crystal molecules may be in a range from 0 degrees to about 45 degrees.

The cross-sectional area of liquid crystal molecules is formed relatively small when a three-dimensional image is provided, so that image luminance is increased and light leakage is prevented. The display device has increased display quality and overcomes the problem of uneven display quality caused by the tilt of the lenses.

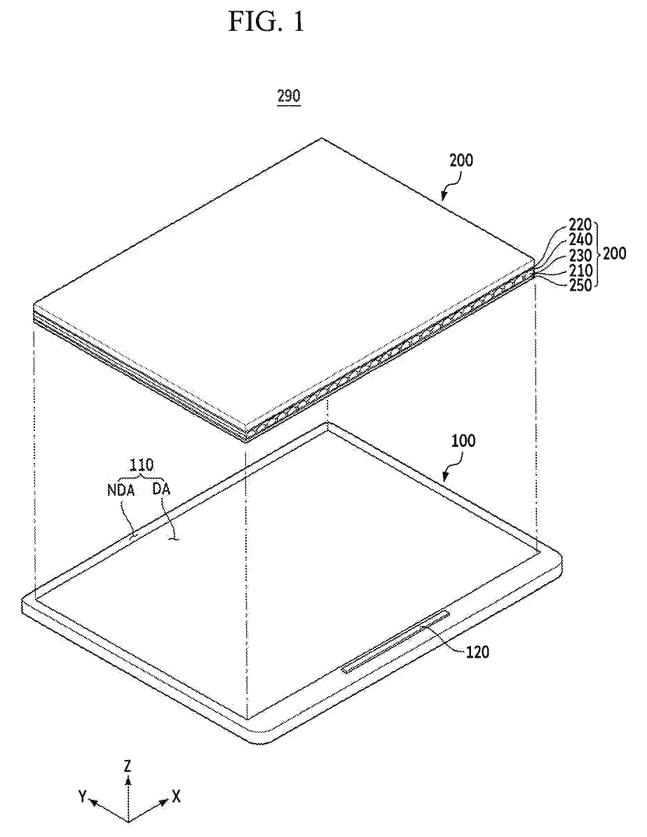

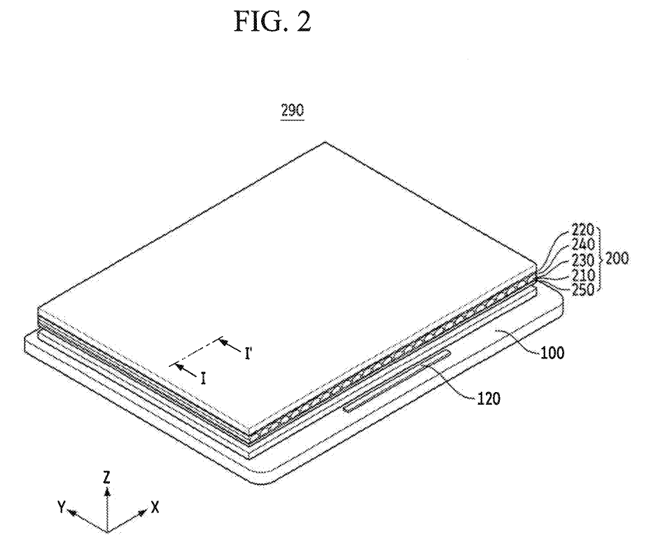

FIG. 1 is an exploded, perspective view showing a display device according to an embodiment of the present disclosure. FIG. 2 is a perspective view of the display device of FIG. 1.

A display device 290 may be implemented as a flat panel display device such as a liquid-crystal display (LCD) device, a field emission display (FED) device, a plasma display panel (PDP) device, and an organic light-emitting display (OLED) device.

The display device 290 may be a stereoscopic image display device including a display module 100 and an optical member 200, e.g., a three-dimensional image display device. To display three-dimensional images, the three-dimensional image display device separately displays a left-eye image and a right-eye image on the front side to give a viewer 3D experiences utilizing binocular parallax. Furthermore, the three-dimensional image display device may separately provide images at different viewing angles on the front side of the display device so that different images are displayed at the different viewing angles.

According to an embodiment of the present disclosure, the display device 290 may be a light-field display device that allows different image information to be seen by a viewers' eyes, respectively, by disposing the optical member 200 on the front side of the display module 100. The light-field display device may generate a 3D stereoscopic image by generating a light field by using the display module 100 that displays a two-dimensional image and the optical member 200 that converts the two-dimensional image into a three-dimensional image and displays it. As will be described later, the light-field display device allows a image display light generated in each of the pixels in the display module 100 to form a light field directed to a particular direction (e.g., a particular viewing angle and/or a particular viewpoint) by stereoscopic lenses, pinholes, barriers, or the like included in the optical member 200. In this manner, 3D stereoscopic image information associated with the particular direction can be provided to the viewer.

The display module 100 may include a display panel 110 and a display driver 120.

The display panel 110 may include a display area DA and a non-display areas NDA. The display area DA may include data lines, scan lines, supply voltage lines, and a plurality of pixels connected to the data lines and scan lines. For example, the scan lines may extend in the first direction (e.g., x-axis direction) and be spaced apart from one another in the second direction (e.g., y-axis direction). The data lines and the supply voltage lines may extend in the second direction (e.g., y-axis direction) and be spaced from one another in the first direction (e.g., x-axis direction).

Each pixel (or unit pixel) formed and arranged on the display panel 110 includes the minimum number of sub-pixels capable of emitting white light. For example, in an embodiment each pixel may include three sub-pixels emitting red, green and blue light lights, respectively. Each of the pixels arranged sequentially and repeatedly may be connected to at least one scan line, a data line, and a supply voltage line. Each of the sub-pixels may include thin-film transistors including a driving transistor and at least one switching transistor, a light-emitting element, and a capacitor. When a scan signal is applied from a scan line, each of the pixels receives a data voltage from a data line and supplies a driving current to the light-emitting element according to the data voltage applied to the gate electrode, so that light can be emitted.

Herein, the pixels of the display panel 110 (e.g., the unit pixels) display 2D multi-view images according to the order in which the display driver 120 provides image data. The multi-view images include n view images, where n is a natural number greater than or equal two. Such n view images are generated by capturing images of a particular object (e.g., contents) with n cameras spaced apart from one another by the distance between a person's eyes.

For example, the n view images may include first data obtained by collecting a particular content at a first viewing angle, second data obtained by collecting the content at a second viewing angle, …, the n^{th} data obtained by collecting the content at the nth viewing angle, etc. In an embodiment, the plurality of data (e.g., first data to nth data) generated by capturing particular contents may be digital data.

The display panel 110 may display multi-view images in units of n pixels during an image display period. For example, the display panel 110 may display multi-view images in units of two pixels. For example, two pixels of the display panel 110 may display a multi-view image including two view images. In an embodiment, the display panel 110 may display a multi-view image in units of time-division frames (or sub-frames) according to the time-division driving of the display driver 120. Multi-view images may be displayed in units of two pixels for each time-division frame. In an embodiment, a time-division frame is driven by dividing one frame into 1/2 or 1/3 sub-frames.

The non-display area NDA may be located at the edge of the display panel 110 to surround the display area DA (e.g., in a plan view). In an embodiment, the non-display area NDA may include a scan driver that applies scan signals to scan lines, and pads connected to the display driver 120. For example, the display driver 120 may be located on one side of the non-display area NDA, and the pads may be located on one edge of the non-display area NDA where the display driver 120 is located.

The display driver 120 may output control signals and image data voltages for driving the display panel 110 in units of at least one frame or at least one time-division frame (or sub-frame). For example, the display driver 120 may supply image data voltages to the data lines in units of at least one time-division frame (or sub-frame). The display driver 120 supplies supply voltage to the supply voltage line, and may supply scan control signals to the scan driver. The image data voltage may include a plurality of data voltages applied to a plurality of pixels (or sub-pixels) connected to a plurality of data lines.

In an embodiment, the optical member 200 includes an optical lens unit (e.g., a refractive index anisotropic lens 230) formed between the first and second base substrates 210 and 220 (e.g., in a z-axis direction), a polarization controller 250 stacked on the optical lens unit 230 to overlap it, and a filler layer 240 located between the optical lens unit 230 and the second base substrate 220 (e.g., in the z-axis direction).

In an embodiment, the display driver 120 may be implemented as an integrated circuit (IC) and may be disposed in the non-display area NDA of the display panel 110 by a chip on glass (COG) technique, a chip on plastic (COP) technique, or an ultrasonic bonding. For another example, the display driver 120 may be mounted on a circuit board and connected to the pads of the display panel 110.

The optical member 200 may be located on the front side of the display panel 110 or the display module 100. In an embodiment, the optical member 200 may be attached to one surface of the display panel 110 or the display area DA through an adhesive member. In an embodiment, the optical member 200 may be attached to the front surface of the display module 100 by a panel bonding apparatus.

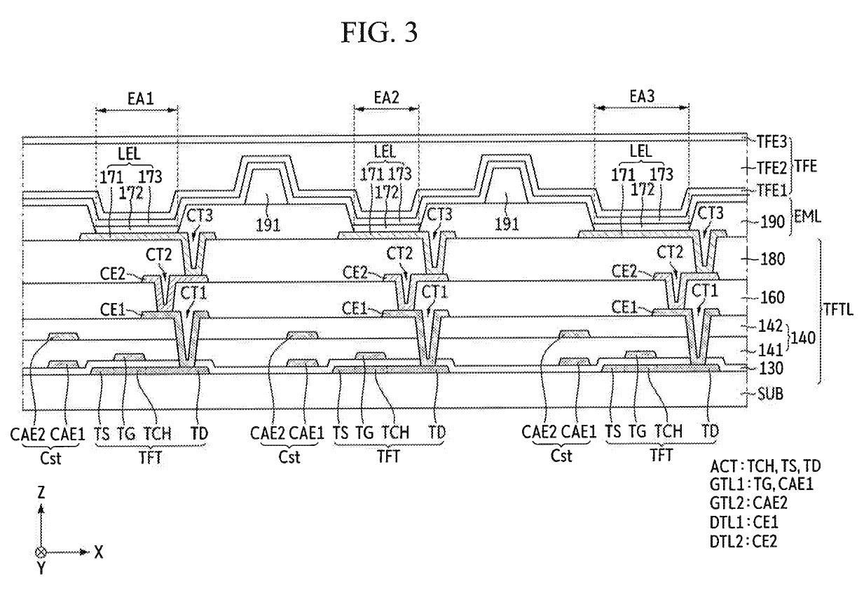

FIG. 3 is a cross-sectional view showing a part of a display device including emission areas.

Referring to FIG. 3, the display panel 110 may include the substrate SUB, the thin-film transistor layer TFTL, the emission material layer EML, and the encapsulation layer TFE.

The thin-film transistor layer TFTL may include an active layer ACT, a first gate metal layer GTL1, a second gate metal layer GTL2, a first data metal layer DTL1, and a second data metal layer DTL2. In addition, the thin-film transistor layer TFTL may include a buffer film BF, a gate insulator 130, a first interlayer dielectric layer 141, a second interlayer dielectric layer 142, a first planarization layer 160, and a second planarization layer 180. The thin-film transistor layer TFTL may include a plurality of thin-film transistors TFT. Each of the thin-film transistors includes a channel TCH, a gate electrode TG, a first electrode TS and a second electrode TD.

The active layer ACT may be disposed on the substrate SUB (e.g., disposed directly thereon in the z-axis direction). In an embodiment, the active layer ACT may include silicon semiconductor such as polycrystalline silicon, monocrystalline silicon and low-temperature polycrystalline silicon, or may include oxide semiconductor.

The active layer ACT may include a channel TCH, a first electrode TS and a second electrode TD of each of the thin-film transistors TFT. The channel TCH may be a region overlapping with the gate electrode TG of the thin-film transistor TFT in the third direction (e.g., z-axis direction), which is the thickness direction of the substrate SUB. The first electrode TS may be disposed on one side of the channel TCH, and the second electrode TD may be disposed on the opposite side of the channel TCH. The first electrode TS and the second electrode TD may not overlap with the gate electrode TG in the third direction (e.g., in the z-axis direction). The first electrode TS and the second electrode TD may be regions having conductivity by doping ions in a silicon semiconductor or an oxide semiconductor.

The gate insulator 130 may be located on (e.g., disposed directly thereon) the active layer ACT. In an embodiment, the gate insulator 130 may include an inorganic layer, for example, a silicon nitride layer, a silicon oxynitride layer, a silicon oxide layer, a titanium oxide layer, or an aluminum oxide layer.

The first gate metal layer GTL1 may be located on the gate insulator 130 (e.g., disposed directly thereon in the z-axis direction). In an embodiment, the first gate metal layer GTL1 may include the gate electrode TG of each of the thin-film transistors TFT and a first capacitor electrode CAE1. In an embodiment, the first gate metal layer GTL1 may be made up of a single layer or multiple layers of one of molybdenum (Mo), aluminum (Al), chromium (Cr), gold (Au), titanium (Ti), nickel (Ni), neodymium (Nd) and copper (Cu) or an alloy thereof.

The first interlayer dielectric layer 141 may be located over the first gate metal layer GTL1. The first interlayer dielectric layer 141 may include an inorganic layer, for example, a silicon nitride layer, a silicon oxynitride layer, a silicon oxide layer, a titanium oxide layer, or an aluminum oxide layer.

The second gate metal line GTL2 may be located on the first interlayer dielectric layer 141 (e.g., disposed directly thereon in the z-axis direction). The second gate metal layer GTL2 may include a second capacitor electrode CAE2. The second capacitor electrode CAE2 may overlap the first capacitor electrode CAE1 in the third direction (e.g., the z-axis direction). In an embodiment, the capacitor Cst may include a first capacitor electrode CAE1 and a second capacitor electrode CAE2. In an embodiment, the second gate metal layer GTL2 may be made up of a single layer or multiple layers of one of molybdenum (Mo), aluminum (Al), chromium (Cr), gold (Au), titanium (Ti), nickel (Ni), neodymium (Nd) and copper (Cu) or an alloy thereof.

The second interlayer dielectric layer 142 may be located over the second gate metal layer GTL2. In an embodiment, the second interlayer dielectric layer 142 may include an inorganic layer, for example, a silicon nitride layer, a silicon oxynitride layer, a silicon oxide layer, a titanium oxide layer, or an aluminum oxide layer.

The first data metal layer DTL1 including a first connection electrode CE1 may be disposed on the second interlayer dielectric layer 142 (e.g., disposed directly thereon in the z-axis direction). In an embodiment, the first connection electrode CE1 may be connected to the first electrode TS or the second electrode TD of the thin-film transistor TFT through a first contact hole CT1 penetrating the gate insulator 130, the first interlayer dielectric layer 141 and the second interlayer dielectric layer 142. In an embodiment, the first data metal layer DTL1 may be made up of a single layer or multiple layers of one of molybdenum (Mo), aluminum (Al), chromium (Cr), gold (Au), titanium (Ti), nickel (Ni), neodymium (Nd) and copper (Cu) or an alloy thereof.

The first planarization layer 160 may be placed on (e.g., disposed directly thereon) the first data metal layer DTL to provide a flat surface over the height differences of the active layer ACT, the first gate metal layer GTL1, the second gate metal layer GTL2, and the first data metal layer DTL. In an embodiment, the first planarization layer 160 may include an organic layer such as an acryl resin, an epoxy resin, a phenolic resin, a polyamide resin and a polyimide resin.

A second data metal layer DTL2 may be disposed on the first planarization layer 160 (e.g., disposed directly thereon in the z-axis direction). The second data metal layer DTL2 may include a second connection electrode CE2. The second connection electrode CE2 may be connected to the first connection electrode CE1 through a second contact hole CT2 penetrating the first planarization layer 160. In an embodiment, the second data metal layer DTL2 may be made up of a single layer or multiple layers of one of molybdenum (Mo), aluminum (Al), chromium (Cr), gold (Au), titanium (Ti), nickel (Ni), neodymium (Nd) and copper (Cu) or an alloy thereof.

The second planarization layer 180 may be located on (e.g., disposed directly thereon) the second data metal layer DTL2. In an embodiment, the second planarization layer 180 may be formed as an organic layer such as an acryl resin, an epoxy resin, a phenolic resin, a polyamide resin and a polyimide resin.

An emission material layer EML may be located on the second planarization layer 180 (e.g., disposed directly thereon in the z-axis direction). The emission material layer EML may include a plurality of light-emitting elements LEL and a pixel-defining layer 190. In an embodiment, each of the light-emitting elements LEL may be, but is not necessarily limited to, an organic light-emitting diode including a pixel electrode 171, an emissive layer 172 and a common electrode 173.

The pixel electrode 171 may be located on the second planarization layer 180 (e.g., disposed directly thereon in the z-axis direction). In an embodiment, the pixel electrode 171 may be connected to the second connection electrode CE2 through a third contact hole CT3 penetrating the second planarization layer 180.

In an embodiment including the top-emission structure in which light exits from the emissive layer 172 towards the common electrode 173, the pixel electrode 171 may be made of a metal material having a high reflectivity such as a stack structure of aluminum and titanium (Ti / Al / Ti), a stack structure of aluminum and indium tin oxide (ITO) (ITO / Al / ITO), an APC alloy and a stack structure of APC alloy and ITO (ITO / APC / ITO). The APC alloy is an alloy of silver (Ag), palladium (Pd) and copper (Cu).

The pixel-defining layer 190 may be located on (e.g., disposed directly thereon) the second planarization layer 180 to cover the edges of each of the pixel electrodes 171 and expose a central portion of the pixel electrodes 171 to define emission areas EA1, EA2 and EA3. In an embodiment, the pixel-defining layer 190 may be formed of an organic layer such as an acryl resin, an epoxy resin, a phenolic resin, a polyamide resin and a polyimide resin.

In each of the emission areas EA1, EA2 and EA3, the pixel electrode 171, the emissive layer 172 and the common electrode 173 are stacked on one another sequentially, so that holes from the pixel electrode 171 and electrons from the common electrode 173 are recombined with each other in the emissive layer 172 to emit light.

The emissive layer 172 may be located on the pixel electrode 171. The emissive layer 172 may include an organic material to emit light of a particular color. For example, in an embodiment the emissive layer 172 may include a hole transporting layer, an organic material layer, and an electron transporting layer.

The common electrode 173 may be located on the emissive layer 172. The common electrode 173 may cover the emissive layer 172. In an embodiment, the common electrode 173 may be a common layer formed across the emission areas EA1, EA2 and EA3. A capping layer may be formed on the common electrode 173.

In an embodiment, in the top-emission organic light-emitting diode, the common electrode 173 may include a transparent conductive material (TCP) such as ITO and IZO that can transmit light, or a semi-transmissive conductive material such as magnesium (Mg), silver (Ag) and an alloy of magnesium (Mg) and silver (Ag). When the common electrode 173 is made of a semi-transmissive metal material, the light extraction efficiency can be increased by using microcavities.

A spacer 191 may be disposed on the pixel-defining layer 190 (e.g., disposed directly thereon in the z-axis direction). The spacer 191 may support a mask during a process of fabricating the emissive layer 172. In an embodiment, the spacer 191 may be implemented as an organic layer such as an acryl resin, an epoxy resin, a phenolic resin, a polyamide resin and a polyimide resin.

The encapsulation film TFE may be disposed on the common electrode 173 (e.g., disposed directly thereon in the z-axis direction). In an embodiment, the encapsulation layer TFE may include at least one inorganic film to prevent permeation of oxygen or moisture into the emission material layer EML. In addition, the encapsulation layer TFE may include at least one organic film to protect the emission material layer EML from particles such as dust. For example, the encapsulation layer TFE may include a first inorganic encapsulation layer TFE1, an organic encapsulation layer TFE2 and a second inorganic encapsulation layer TFE3.

In an embodiment, the first inorganic encapsulation film TFE1 may be located on the common electrode 173, the organic encapsulation film TFE2 may be located on the first inorganic encapsulation film TFE1, and the second inorganic encapsulation film TFE3 may be located on the organic encapsulation film TFE2. In an embodiment, the first inorganic encapsulation film TFE1 and the second inorganic encapsulation film TFE3 may be made up of multiple layers in which one or more inorganic layers of a silicon nitride layer, a silicon oxynitride layer, a silicon oxide layer, a titanium oxide layer and an aluminum oxide layer are alternately stacked on one another. The organic encapsulation film TFE2 may be an organic film such as an acryl resin, an epoxy resin, a phenolic resin, a polyamide resin, a polyimide resin, etc.

In the example shown in the drawings, the third emission area EA3 is larger than the first emission area EA1, and the first emission area EA1 is larger than the second emission area EA2. In an embodiment, the first emission area EA1 may be a red emission area, the second emission area EA2 may be a green emission area, and the third emission area EA3 may be a blue emission area. It should be understood, however, that the relative sizes of the emission areas and the respective colors emitted by each of the emission areas are not necessarily limited thereto.

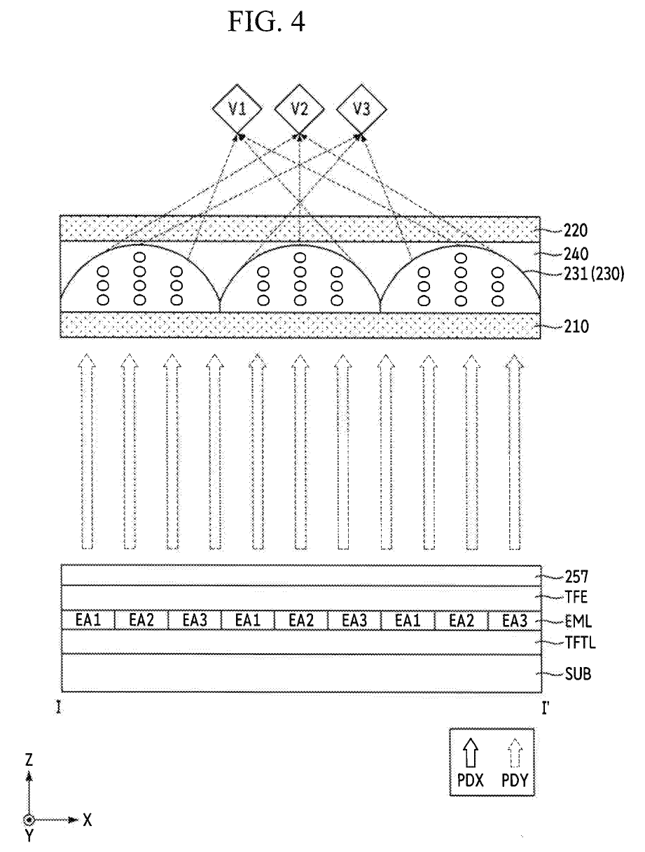

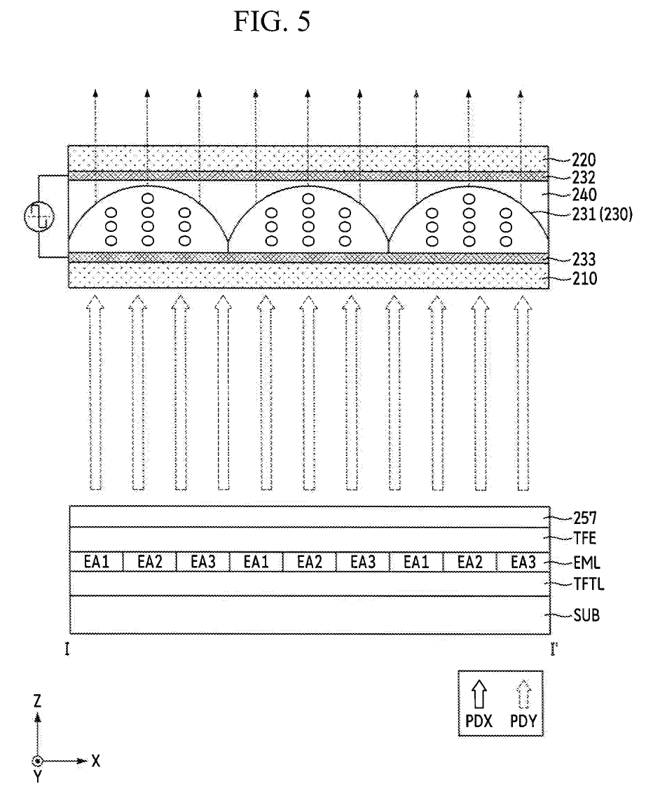

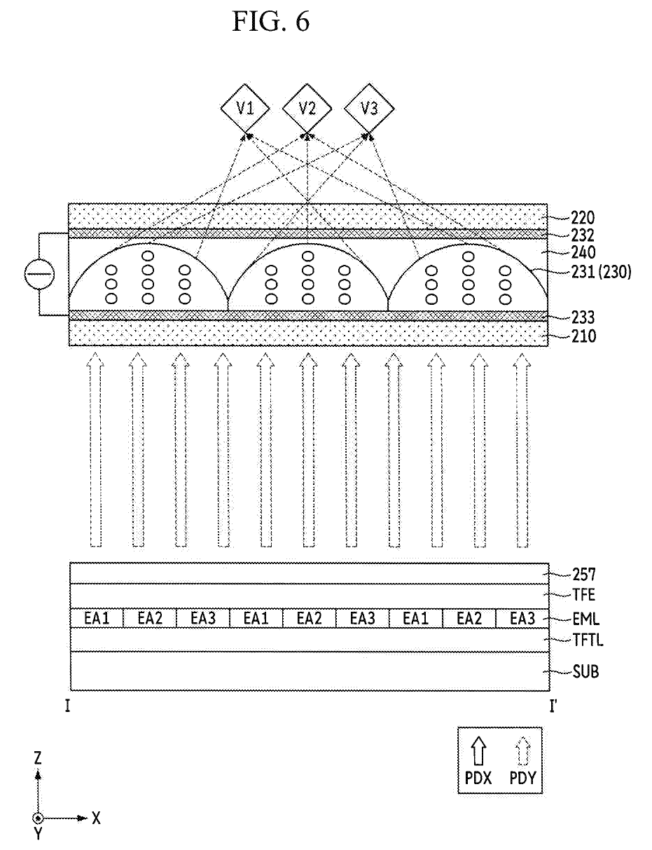

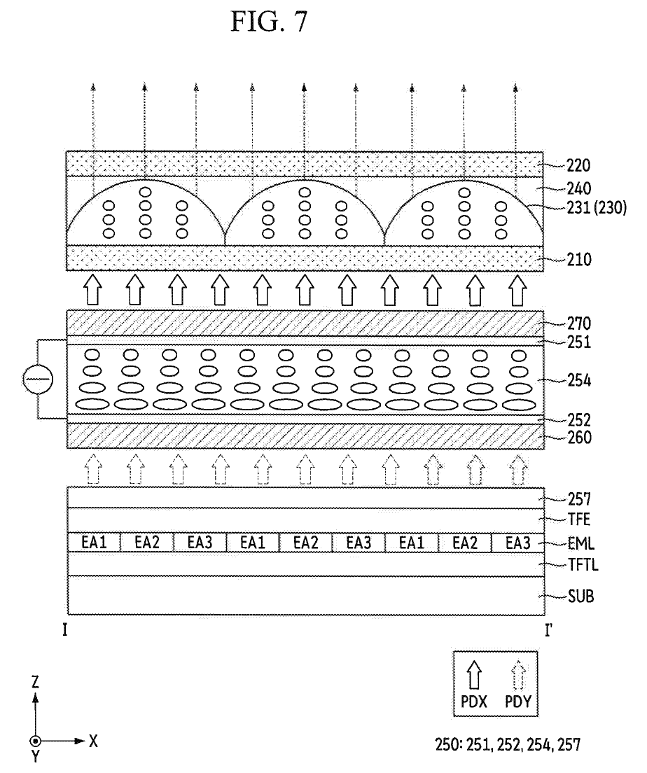

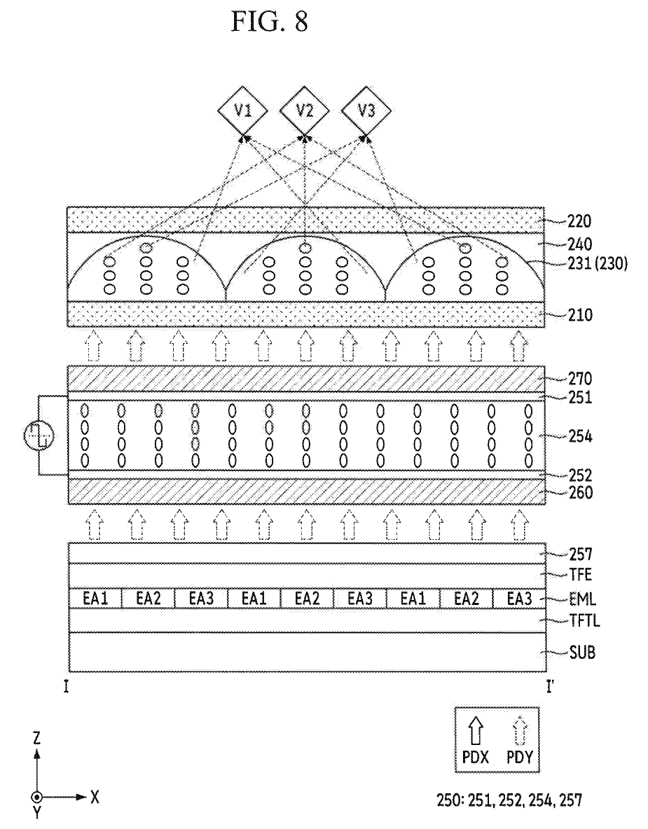

FIG. 4 is a cross-sectional view showing an always-refracting light field display device. FIG. 5 is a cross-sectional view showing a first-type light field display device in which a two-dimensional image is generated. FIG. 6 is a cross-sectional view showing a first-type light field display device in which a three-dimensional image is generated. FIG. 7 is a cross-sectional view showing a second-type light field display device in which a two-dimensional image is generated. FIG. 8 is a cross-sectional view showing a second-type light field display device in which a three-dimensional image is generated.

As described above, the light field display device can display different image information to the viewer's two eyes by arranging an optical member in front of the display module. A light field display device can provide a two-dimensional image or a three-dimensional image.

Particular contents may include not only everything that exists in the real world, such as text, pictures, objects, and things, but also everything that is implemented as digital data and does not exist in the real world. The particular contents may be collected at a first viewing angle to derive first data. The particular contents may be collected at a second viewing angle to derive second data. Besides, if a particular content is collected at the nth viewing angle, the nth data may be derived.

A display device according to an embodiment may include a display panel where a plurality of light-emitting elements is arranged, and an optical member arranged on the display panel (e.g., in the z-axis direction). Light emitted from a light-emitting element arranged on the display panel may or may not be refracted while passing through the optical member, depending on whether a three-dimensional image is generated or not. For example, in an embodiment, to generate a three-dimensional image, light emitted from a light-emitting element may be refracted at the optical member. For example, to generate a two-dimensional image, light emitted from a light-emitting element may not be refracted at the optical member.

However, even when a two-dimensional image is generated, light emitted from a light-emitting element may be refracted. When this happens, the resolution of the display device may deteriorate.

By controlling the direction in which light emitted from a plurality of light-emitting elements is refracted, a viewing angle may be given to each of the plurality of light-emitting elements. This may be referred to as viewing angle mapping. In an embodiment, the pitch, tilt angle, etc. of a lens (e.g., a slanted lens) included in the optical member may be adjusted to control the direction of light emitted from the light-emitting element.

A particular viewing angle may be mapped to each of the plurality of light-emitting elements. The light emitted from the mapped light-emitting element may travel in the given viewing angle direction. For example, in an embodiment light emitted from a light-emitting element to which a first viewing angle is mapped may travel in a first viewing angle direction where the first viewing area is located, and light emitted from a light-emitting element to which a second viewing angle is mapped may travel in a second viewing angle direction where the second viewing area is located.

First data obtained by collecting a particular content at the first viewing angle may be input to the light-emitting element to which the first viewing angle is mapped. The second data may be input to the light-emitting element to which the second viewing angle is mapped.

The first viewing angle may be located on one side (e.g., the left-eye side) of the center of the user's eyes. The second viewing angle may be located on the other side (e.g., the right-eye side) of the center of the user's eyes.

Regardless of which viewing angle is mapped, if different images are perceived by the user's left and right eyes respectively, the user may feel that a three-dimensional image is being generated from the display device. If the same image is perceived by the user's left and right eyes, the user may feel that a two-dimensional image is generated from the display device. The same image may be perceived by the user's left and right eyes when the light output from the display panel is not refracted. However, even if the light output from the display panel is refracted as described above, the same image may be perceived by the user's left and right eyes. When this happens, the resolution of the display device may deteriorate.

Therefore, the user can experience a three-dimensional image from an image generated by inputting the first data into the light-emitting element to which the first viewing angle is mapped, and inputting the second data into the light-emitting element to which the second viewing angle is mapped.

On the other hand, the user can experience a two-dimensional image from the image generated by inputting the first data to both the light-emitting element to which the first viewing angle is mapped and the light-emitting element to which the second viewing angle is mapped. Light emitted from the light-emitting element to which the first viewing angle is mapped is still refracted even when a two-dimensional image is implemented, and light emitted from the light-emitting element to which the second viewing angle is mapped is also still refracted.

On the other hand, two-dimensional images may be generated even when the light emitted from the light-emitting element is not refracted by the optical member. This allows the user to perceive a two-dimensional image because none of the lights emitted from the light-emitting elements is refracted regardless of the viewing angles mapped to the light-emitting elements. The resolution of such a two-dimensional image may be greater than the resolution of a two-dimensional image generated when the same image is perceived by the user's left and right eyes even though the light is refracted.

For example, a two-dimensional image may be implemented when the light emitted from the light-emitting element is not refracted by the optical member, or when the same data is input to both eyes of the user even if the light is refracted. In addition, the resolution may vary depending on whether the light is refracted or not.

Light field display devices may include: a switchable display device that can provide either a two-dimensional image or a three-dimensional image by controlling, such as electrically controlling, whether to refract light output from the display panel or not; and an always-refracting display device that always causes light output from the display panel to be refracted. Even in the always-refracting display device in which light output from the display panel is always refracted, a two-dimensional image can be generated if the same data is input regardless of the viewing angle mapped to the light-emitting element as described above. When two-dimensional images are generated in the always-refracting display devices, the resolution may be degraded.

In an embodiment, a switchable display device may control the linear polarization direction of light output from the display panel and determine whether to provide either a two-dimensional image or a three-dimensional image by utilizing the refractive index anisotropy of the lenses included in the optical lens unit.

For example, in an embodiment the light output from the display panel may pass through a polarizing member arranged on the display panel and may be output along a path in the second linear polarization direction.

According to an embodiment of the present disclosure, the short-axis direction of the lenses included in the optical lens unit may coincide with the first linear polarization direction. The long-axis direction of the lenses may coincide with the second linear polarization direction.

The optical lens unit may further include a filler layer located over a plurality of lenses. The plurality of lenses may have birefringent characteristics. For example, in an embodiment the refractive index of the lenses in the short-axis direction may be equal to the refractive index of the filler layer, and the refractive index of the lenses in the long-axis direction may be greater than the refractive index of the filler layer. It should be understood, however, that embodiments of the present disclosure are not necessarily limited thereto.

With the above refractive indexes, when voltage is applied to a lens, the short-axis direction of the lens may be parallel to the path in the second linear polarization direction. When light that is output from the display panel and has the path in the second linear polarization direction passes through the lens, the light may undergo a refractive index in the short-axis direction that coincides with the second linear polarization direction. Since the refractive index of the lenses in the short-axis direction is equal to the refractive index of the filler layer, light passing through the lens may travel straight without being refracted at the boundary between the lenses and the filler layer. Since the light is not refracted, the light perceived by the user's two eyes is straight light, and the user may feel (e.g., perceive) that a two-dimensional image is provided. Such mechanism may be applied to a first-type light field display device in which a two-dimensional image is generated (see FIG. 5).

In an embodiment, when no voltage is applied to the lens, the long-axis direction of the lens may be parallel to the path in the second linear polarization direction. When light that is output from the display panel and has the path in the second linear polarization direction passes through the lens, the light may undergoes a refractive index in the long-axis direction that coincides with the second linear polarization direction. Since the refractive index of the lenses in the long-axis direction is greater than the refractive index of the filler layer, light passing through the lenses may be refracted at the boundary between the lenses and the filler layer. Since the refractive index of the major axis of the lenses is greater than the refractive index of the filler layer, light passing through the lenses may be refracted at the boundary between the lenses and the filler layer. Since the light is refracted, the light perceived by the user's two eyes is refracted light, and the user may feel (e.g., perceive) that a thee-dimensional image is provided. Such mechanism may be applied to a first-type light field display device in which a three-dimensional image is generated (see FIG. 6).

In the second-type light field display device, no voltage may be applied to the lenses, and the short-axis direction and the long-axis direction of the lenses may be fixed such that they are parallel to the first linear polarization direction and the second linear polarization direction, respectively (see FIGS. 7 and 8). Instead, the light output from the display panel having a path in the second linear polarization direction may pass through separate driving liquid crystals arranged between driving electrodes. The path of the light passing through the driving liquid crystals to which no voltage is applied is converted to a path in the first linear polarization direction and may pass through the driving liquid crystals (see FIG. 7). The light passing through the driving liquid crystals to which a voltage is applied maintains a path in the second linear polarization direction and may pass through the driving liquid crystals (see FIG. 8).

Since the short-axis direction and the long-axis direction of the lenses are parallel to the first linear polarization direction and the second linear polarization direction, respectively, when the light passing through the driving liquid crystals has a path in the first linear polarization direction, the light may undergo the refractive index in the short-axis direction of the lenses. When light passing through the driving liquid crystals has a path in the second linear polarization direction, the light may undergo the refractive index in the long-axis direction of the lens. Since the refractive index of the lenses in the short-axis direction is equal to the refractive index of the filler layer, and the refractive index in the long-axis direction is greater than the refractive index of the filler layer, the light is refracted or is not refracted at the boundary between the lenses and the filler layer depending on the linear polarization direction of the light passing through the driving liquid crystals.

As described above, the switchable light field display device may include a first-type light field display device (see FIGS. 5 and 6), and a second-type light field display device (see FIGS. 7 and 8).

In the first-type light field display device, the linear polarization direction of light passing through the display panel is not changed as described above. Instead, the first-type light field display device may directly change the long-axis direction and the short-axis direction of a lens having a birefringent characteristic. A changed axis direction coincides with the linear polarization direction of light passing through the display panel, and the light may pass through the boundary while undergoing the refractive index of the changed axis direction.

In the second-type light field display device, the linear polarization direction of the light passing through the display panel may be changed as it passes through the driving liquid crystals. Instead, the second-type light field display device cannot directly change the longer axis direction and the shorter axis direction of a lens having a birefringent characteristic. Accordingly, the linear polarization direction of the light passing through the driving liquid crystals coincides with the fixed axis direction of the lens, and the light may pass through the boundary while undergoing the refractive index in the fixed axis direction.

Referring to FIGS. 7 and 8, in the second-type light field display device, the display panel may include a substrate SUB, a thin-film transistor layer TFTL, an emission material layer EML, and an encapsulation layer TFE.

The substrate SUB may have rigidity to support an element formed on the substrate SUB. For example, in an embodiment the substrate SSUB may be a glass substrate or a plastic substrate such as polyethylene terephthalate (PET).

The thin-film transistor layer TFTL may be located on the substrate SUB (e.g., in the z-axis direction). The thin-film transistor layer TFTL may adjust the brightness of the display device 290. The thin-film transistor layer TFTL may include transistors.

The emission material layer EML may be located on the thin-film transistor layer TFTL (e.g., in the z-axis direction). The emission material layer EML may include first to third emission areas EA1, EA2 and EA3. The first to third emission areas EA1, EA2 and EA3 may be arranged sequentially and repeatedly.

The encapsulation layer TFE may be disposed on the emission material layer EML (e.g., in the z-axis direction). The encapsulation layer TFE may include at least one inorganic film and at least one organic film for encapsulating the emission material layer.

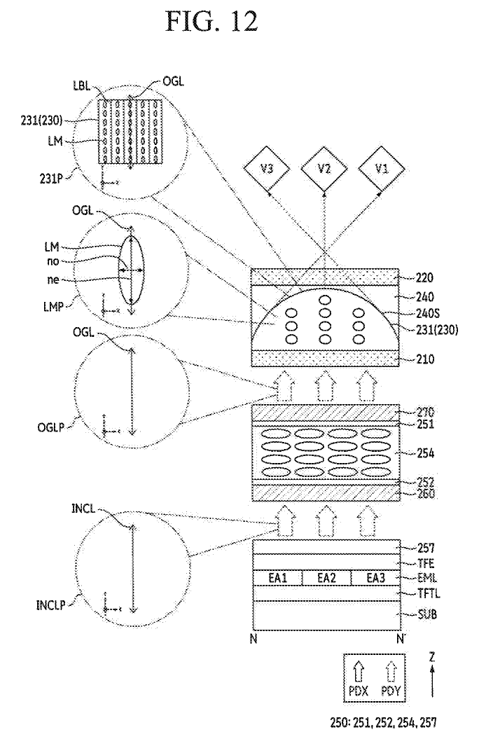

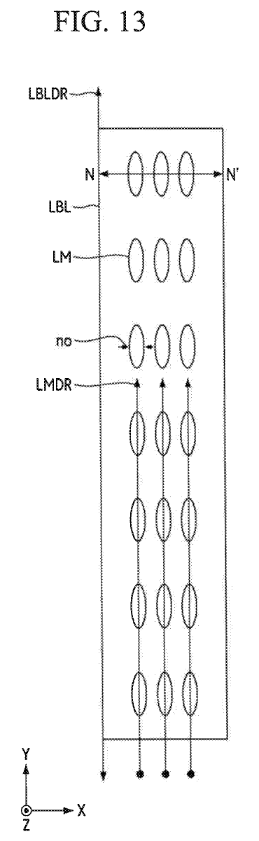

In an embodiment, the optical member may include an optical lens unit 230 located between a first base substrate 210 and a second base substrate 220 (e.g., in the z-axis direction). The optical lens unit 230 may include a plurality of lenses 231. The optical member may include a filler layer 240 located between the first base substrate 210 and the second base substrate 220. The plurality of lenses 231 may be spaced apart from each other with a boundary (LBL; FIGS. 12-13) between them. Although the filler layer 240 is located over the optical lens unit 230 in the drawings, embodiments of the present disclosure are not necessarily limited thereto. For example, in some embodiments light passing through the display panel may first pass through the filler layer 240 and then pass through the optical lens unit 230. In addition, although the lenses 231 in the optical lens unit 230 are convex in the third direction (e.g., in the z-axis direction) in the drawings, embodiments of the present disclosure are not necessarily limited thereto.

As described above, the refractive index range of the material having refractive index anisotropy in the lens 231 and the refractive index value of the filler layer 240 are controlled, and accordingly light may or may not be refracted depending on whether there is a difference in refractive index. Therefore, the vertical positions of the optical lens unit 230 and the filler layer 240, the convex direction of the lens 231, etc., fall within the scope of the invention that those skilled in the art can simply design and modify according to embodiments.

The first base substrate 210, the second base substrate 220, the third base substrate 260 and the fourth base substrate 270 may include a material that allows light to pass through, such as glass and plastic.

In an embodiment, a polarization controller 250 may be formed on the rear side of the first base substrate 210 or the front side of the display panel to convert a two-dimensional image display light of the display panel to a path PDY in the first linear polarization direction or the second linear polarization direction to output it. In an embodiment, the polarization controller 250 may include a first driving electrode 251, a second driving electrode 252, and driving liquid crystals 254 arranged between the first driving electrode 251 and the second driving electrode 252. The polarization controller 250 may further include a polarizing member 257 located on the display panel.

The polarization controller 250 may allow the light incident on the path PDX in the first linear polarization direction through the polarizing member 257 to pass through it by maintaining the path PDX in the first linear polarization direction or by converting the path to the path PDY in the second linear polarization direction.

The polarization controller 250 may allow the light incident on the path PDX in the first linear polarization direction through the polarizing member 257 to pass through it by converting the path to a path in a linear polarization layer direction between the first linear polarization layer direction and the second linear polarization direction.

For example, in an embodiment the first linear polarization direction may be parallel to the first direction (e.g., the x-axis direction), and the second linear polarization direction may be parallel to the second direction (e.g., the y-axis direction). It should be understood, however, that embodiments of the present disclosure are not necessarily limited thereto.

At least some elements 251, 252 and 254 of the polarization controller 250 may be arranged between the third base substrate 260 and the fourth base substrate 270 (e.g., in the z-axis direction). The other elements 257 of the polarization controller 250 may be arranged between the display panel and the third base substrate 260 (e.g., in the z-axis direction).

The first driving electrode 251 may be placed between the third base substrate 260 and the fourth base substrate 270 (e.g., in the z-axis direction). A voltage may be applied to the first driving electrode 251.

The second driving electrode 252 may be placed between the third base substrate 260 and the first driving electrode 251 (e.g., in the z-axis direction). The second driving electrode 252 may be parallel to the first driving electrode 251. The shape of the second driving electrode 252 may conform to the shape of the first driving electrode 251. A voltage may be applied to the second driving electrode 252. In an embodiment, the driving liquid crystals 254 may control the linear polarization direction of light by the difference between the voltage applied to the first driving electrode 251 and the voltage applied to the second driving electrode 252.

The polarizing member 257 may be placed (e.g., disposed) between the display panel and the third base substrate 260 (e.g., in the z-axis direction). Light output from the display panel may vibrate in all directions. The polarizing member 257 may transmit only the light vibrating in a particular direction among the lights output from the display panel and block the others. According to an embodiment of the present disclosure, the polarizing member 257 may transmit only light having the path PDX in the first linear polarization direction among the lights output from the display panel, but embodiments of the present disclosure are not necessarily limited thereto.

The driving liquid crystals 254 may be arranged between the first driving electrode 251 and the second driving electrode 252 (e.g., in the z-axis direction). The driving liquid crystals 254 may include liquid crystals that are birefringent material. The arrangement of the driving liquid crystals 254 may change depending on the difference in voltages applied to the first driving electrode 251 and the second driving electrode 252. In an embodiment, the driving liquid crystals 254 may be TN (twisted nematic) liquid crystals.

Referring to FIG. 7, the difference between the voltage applied to the first driving electrode 251 and the voltage applied to the second driving electrode 252 during the two-dimensional image display period may be less than or equal to a predetermined value. The driving liquid crystals 254 may convert the linear polarization direction of the incident light having the path PDY in the second linear polarization direction. The light passing through the driving liquid crystals 254 may have the path PDX in the first linear polarization direction.

Referring to FIG. 8, the difference between the voltage applied to the first driving electrode 251 and the voltage applied to the second driving electrode 252 during a two-dimensional image display period may be greater than or equal to a predetermined value. The driving liquid crystals 254 may maintain the linear polarization direction of the incident light having the path PDY in the second linear polarization direction. The light passing through the driving liquid crystals 254 may still have the path PDY in the second linear polarization direction.

Referring back to FIGS. 7 and 8, the first base substrate 210, the second base substrate 220 and the optical lens unit 230 located between the substrates 210 and 220 may be placed on the fourth base substrate 270. The optical lens unit 230 may be formed in the form of a sheet of lenses arranged in parallel. The polarization controller 250 may overlap with the optical lens unit 230 in the form of the sheet of lenses and may be stacked on it.

The optical lens unit 230 may include a plurality of lenses 231.

The light passing through the lenses 231 may undergo the refractive index in the long-axis direction of the lenses 231, the refractive index in the short-axis direction, or countless refractive indices in the directions between the long axis and the short-axis directions, depending on the arrangement of the birefringent materials (e.g., liquid crystals or slits) included in the lenses 231. The innumerable refractive indices in the directions between the long axis and the short-axis directions of the lenses 231 may be less than the refractive index in the long-axis direction and greater than the refractive index in the short-axis direction, but embodiments of the present disclosure are not necessarily limited thereto. For example, in some embodiments the innumerable refractive indices in the directions between the long axis and the short-axis directions of the lenses 231 may be less than the refractive index in the short-axis direction and greater than the refractive index in the long-axis direction.

According to embodiments of the present disclosure, the long-axis direction of the lenses 231 may be parallel to the first direction (e.g., the x-axis direction), and the short-axis direction of the lenses 231 may be parallel to the second direction (e.g., the y-axis direction). In addition, the refractive index of the filler layer 240 over the lenses 231 may be equal to the refractive index in the short-axis direction of the lenses 231 and less than the refractive index in the long-axis direction of the lenses 231, but embodiments of the present disclosure are not necessarily limited thereto.

Referring to FIG. 7, the light passing through the driving liquid crystals 254 may have the path PDX in the first linear polarization direction, and the first linear polarization direction may be coincident with or parallel to the first direction (e.g., the x-axis direction). Therefore, the light passing through the driving liquid crystals 254 may undergo the refractive index in the short-axis direction of the lens 231. Since the refractive index of the lens 231 in the short-axis direction is equal to the refractive index of the filler layer 240, the light passing through the driving liquid crystals 254 may travel straight without being refracted at the boundary between the lenses 231 and the filler layer 240. A two-dimensional image may be generated from the second-type light field display device by the light that is not refracted.

Referring to FIG. 8, the light passing through the driving liquid crystals 254 may have the path PDY in the second linear polarization direction, and the second linear polarization direction may be coincident with or parallel to the second direction (e.g., the y-axis direction). Therefore, the light passing through the driving liquid crystals 254 may undergo the refractive index in the long-axis direction of the lens 231. Since the refractive index in the long-axis direction of the lens 231 is greater than the refractive index of the filler layer 240, the light passing through the driving liquid crystals 254 may be refracted at the boundary between the lenses 231 and the filler layer 240. A three-dimensional image may be generated from the second-type light field display device by the light that is not refracted. In an embodiment, the refracted light may travel towards a first view area V1, a second view area V2, and a third view area V3 depending on the mapped viewing angle.

The filler layer 240 may be placed on (e.g., disposed directly thereon) a plurality of lenses 231. The second base substrate 220 may be placed on the filler layer 240 (e.g., disposed directly thereon in the z-axis direction).

The filler layer 240 may include a transparent material that allows light to pass through. For example, the filler layer 240 may include an isotropic polymer material.

In an embodiment, the refractive index of the filler layer 240 may be equal to the refractive index in the short-axis direction of the liquid crystals included in the lenses 231 as described above. The refractive index of the filler layer 240 may be less than the refractive index in the long-axis direction of the liquid crystals included in the lenses 231. Accordingly, the light passing through the lenses 231 may or may not be refracted at the boundary.

Referring to FIGS. 5 and 6, in an embodiment, in the first-type light field display device, the display panel may include a substrate SUB, a thin-film transistor layer TFTL, an emission material layer EML, and an encapsulation layer TFE. The elements having substantially the same functions as those of the second-type light field display device described above are denoted by the same reference numerals. Therefore, the description thereof will not be repeated for economy of explanation.

The polarizing member 257 may be placed (e.g., disposed) between the display panel and the first base substrate 210 (e.g., in the z-axis direction). Light output from the display panel may vibrate in all directions. The polarizing member 257 may transmit only the light vibrating in a particular direction among the lights output from the display panel and block the other lights vibrating in different directions from the particular direction. According to an embodiment of the present disclosure, the polarizing member 257 may transmit only light having the path PDX in the first linear polarization direction among the lights output from the display panel, but embodiments of the present disclosure are not necessarily limited thereto.

The third driving electrode 232 may be placed between the first base substrate 210 and the second base substrate 220 (e.g., in the z-axis direction), and the fourth driving electrode 233 may be placed between the first base substrate 210 and the third driving electrode 232 (e.g., in the z-axis direction). The optical lens unit 230 including lenses 231 may be placed between the third driving electrode 232 and the fourth driving electrode 233 (e.g., in the z-axis direction). Although the filler layer 240 is located over the optical lens unit 230 in the drawings, their positions in the vertical direction may be switched.

Voltage may be applied to the third driving electrode and the fourth driving electrode, and the lenses 231 may include liquid crystals, which are a birefringent material. The alignment, orientation, etc., of the liquid crystals in the lenses 231 may change depending on the difference in voltages applied to the third driving electrode 232 and the fourth driving electrode 233.

Referring to FIG. 6, the difference between the voltage applied to the third driving electrode 232 and the voltage applied to the fourth driving electrode 233 during the three-dimensional image display period may be less than or equal to a predetermined value. The light passing through the display panel may have the path PDY in the second linear polarization direction. The liquid crystals may maintain the alignment direction initially formed by a rubbing process, etc. Therefore, the first linear polarization direction may be coincident with or parallel to the long-axis direction of the liquid crystals in the lenses 231. The light passes while undergoing the refractive index in the long-axis direction of the liquid crystals, and the refractive index in the long-axis direction is greater than the refractive index of the filler layer 240, so that the light may be refracted at the boundary. A three-dimensional image may be generated from the first-type light field display device by the refracted light. The refracted light may travel towards the first view area V1, the second view area V2, and the third view area V3 depending on the mapped viewing angle.

Referring to FIG. 5, the difference between the voltage applied to the third driving electrode 232 and the voltage applied to the fourth driving electrode 233 during the two-dimensional image display period may be greater than or equal to a predetermined value. The light passing through the display panel may have the path PDY in the second linear polarization direction. The liquid crystals may be changed to a direction different from the direction in which they were initially formed, such as by a rubbing process. Therefore, the second linear polarization direction may be coincident with or parallel to the short-axis direction of the liquid crystals in the lenses 231. The light passes while undergoing the refractive index in the short-axis direction of the liquid crystals, and the refractive index in the short-axis direction is equal to the refractive index of the filler layer 240, so that the light may not be refracted at the boundary. A two-dimensional image may be generated from the first-type light field display device by the light that is not refracted.

In the foregoing descriptions, it is assumed that the refractive index of the filler layer 240 is equal to the refractive index in the short-axis direction of the lenses 231 and the liquid crystals in the lenses 231 and is less than the refractive index in the long-axis direction. In addition, it is assumed that the linear polarization direction is specified in the light field display devices of the first type and the second type. In addition, it is assumed that in the first-type light field display device, a two-dimensional image is generated when no voltage is applied to the third driving electrode 232 and the fourth driving electrode 233, and a three-dimensional image is generated when voltage is applied. In addition, it is assumed that in the second-type light field display device, a two-dimensional image is generated when no voltage is applied to the first driving electrode 251 and the second driving electrode 252, and a three-dimensional image is generated when voltage is applied. However, embodiments of the present disclosure are not necessarily limited thereto.

It should be noted that this is merely illustrative for convenience of illustration and clarity, etc. variables such as the refractive index range based on birefringence properties of liquid crystals, the refractive index value of the filling layer, and the linear polarization directions of light passing through the individual elements, etc., may be simply modified by those skilled in the art as desired within the scope of the invention.

It should be noted that the long-axis direction and short-axis direction of the liquid crystals in the lenses 231 may be directly changed in the first-type light field display device, while the linear polarization direction of the light passing through the display panel may be directly changed in the second-type light field display device.

Referring to FIG. 4, in an embodiment in the always-refracting display device, the linear polarization direction of light, the alignment direction of liquid crystals, etc. do not change and a three-dimensional image can be always provided, as described above, even in the always-refracting display device, the user can experience a two-dimensional image from the image generated by inputting the first data to both the light-emitting element to which the first viewing angle is mapped and the light-emitting element to which the second viewing angle is mapped. Light emitted from the light-emitting element to which the first viewing angle is mapped is still refracted even when a two-dimensional image is implemented, and light emitted from the light-emitting element to which the second viewing angle is mapped is also still refracted. Unfortunately, since the viewing angles are separated from each other, the light input to one of the eyes may fall below half of the overall resolution of the display panel, which may degrade the resolution. Typically, light is always refracted in the always-refracting display device, and thus three-dimensional images are generated.

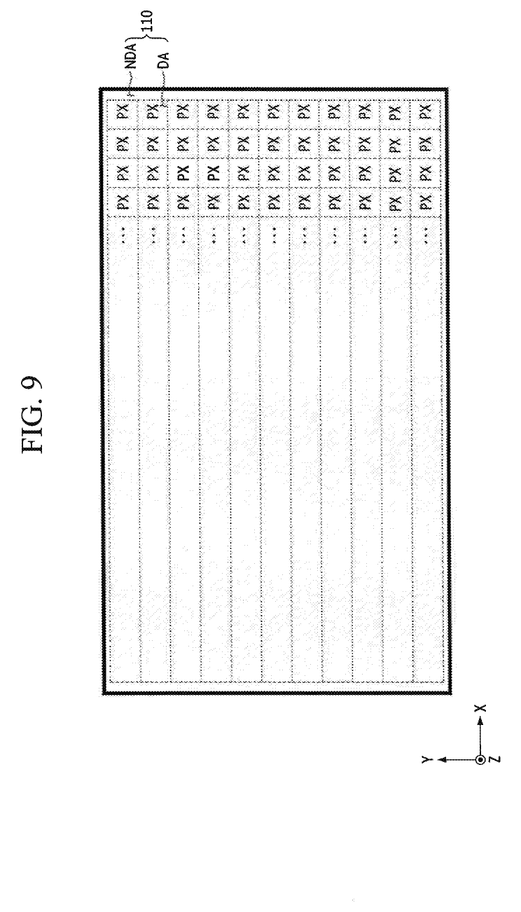

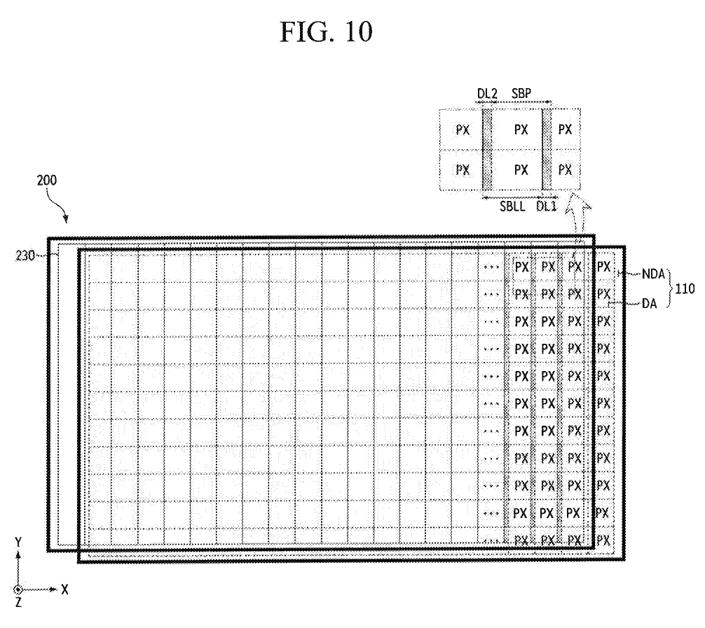

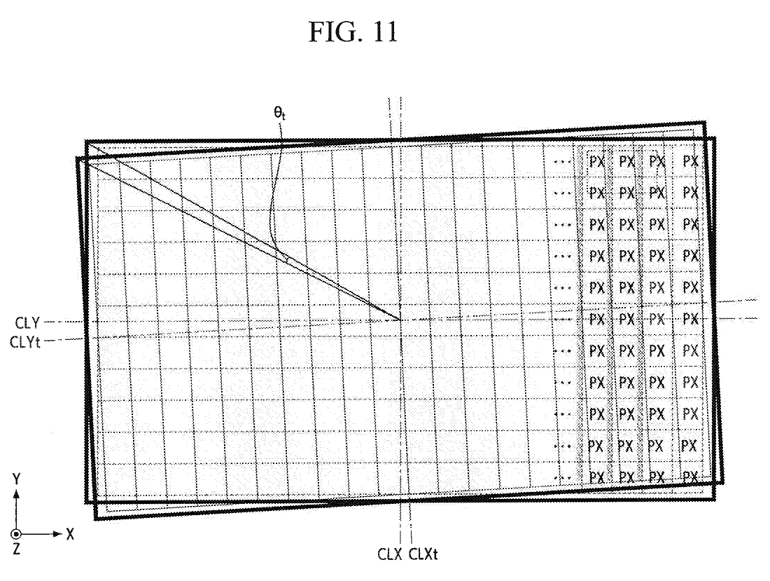

FIG. 9 is a plan view showing a display panel. FIG. 10 is a view showing a moiré pattern that occurs due to the optical lens unit placed on the display panel. FIG. 11 is a view showing tilting an optical lens unit located on a display panel to prevent a moiré pattern.

Referring to FIG. 9, in an embodiment the display panel 110 may include a display area DA and a non-display area NDA surrounding the display area DA (e.g., in a plan view). A plurality of pixels PX may be arranged in the display area DA. In an embodiment, each of the plurality of pixels PX may include a first sub-pixel representing a first color, a second sub-pixel representing a second color, and a third sub-pixel representing a third color. In an embodiment, each of the first color, the second color and the third color may be one selected from the group consisting of red, green and blue, such that the colors are different from one another. For example, the first color may be red, the second color may be green, and the third color may be blue. It should be noted that embodiments of the present disclosure are not necessarily limited thereto and the number of sub-pixels and the colors emitted by the sub-pixels may vary.

Referring to FIG. 10, an optical member 200 may be placed on the display panel 110 (e.g., disposed thereon in the z-axis direction). The optical member 200 may include the optical lens unit 230.

Referring to the enlarged view, a plurality of pixels PX may be arranged at a first spacing SBP, and a plurality of lenses in the optical lens unit 230 placed in the optical member 200 may be arranged at a second spacing SBLL. The first spacing SBP may be equal to or different from the second spacing SBLL.

For example, the boundary between the pixels PX arranged at the first spacing SBP may not overlap the boundary between the lenses arranged at the second spacing SBLL. The first spacing SBP may be different from the second spacing SBLL. For example, there may be spaces having different sizes because the boundary between the pixels PX and the boundary between the lenses that do not overlap each other. For example, the boundary between the pixels PX and the boundary between the lenses do not overlap each other, so that there may be a first boundary gap DL1 and a second boundary gap DL2.

In an embodiment, the first boundary gap DL1 and the second boundary gap DL2 may be smaller than the first spacing SBP and the second spacing SBLL. The interaction of the patterns by the first boundary gap DL1 and the interaction of the patterns by the second boundary gap DL2 may cause a moiré pattern. The moiré pattern may occur by the interaction of a plurality of regular patterns when they overlap each other. The moiré pattern that may occur during the process of attaching the optical member 200 to the display panel 110 may deteriorate the display quality of the display device.

Referring to FIG. 11, to prevent deterioration in the display quality due to the moiré pattern, the optical member 200 attached to the display panel 110 may be tilted at a certain angle.

In an embodiment, in the fabrication process, the optical member 200 may be tilted to derive an angle θₜ at which the moiré pattern is minimized.

For example, a first central axis CLY extended in the first direction from the display panel 110, and a second central axis CLX extended in the second direction intersecting the first direction may be defined. The first direction may be the x-axis direction, and the second direction may be the y-axis direction, for example. The first direction and the second direction may be orthogonal to each other, but embodiments of the present disclosure are not necessarily limited thereto and the first and second directions may intersect each other at various different angles. In addition, a third central axis CLYt extended in the first direction from the optical member 200, and a fourth central axis CLXt extended in the second direction may be defined.

In an embodiment, the angle between the first central axis CLY and the third central axis CLYt may be equal to the angle between the second central axis CLX and the fourth central axis CLXt, which may be the angle θₜ at which the moiré pattern is minimized.

Light that is output from the display panel 110 and passes through the optical member 200 is refracted or travels straight to provide a three-dimensional image or a two-dimensional image, as described above. For a variety of reasons including the above-described reasons, when the optical member 200 is tilted at the angle θt, the light that is output from the display panel 110 and passes through the optical member 200 may be refracted at a different refraction angle than the designed refraction angle. Alternatively, when the optical member 200 is tilted by the angle θt, the refractive index according to the position of the lens is not substantially the same, but the refractive index of the light may be different depending on the position of the lens through which the light passes. Therefore, the light may be refracted by a relatively high refractive index when passing through a certain position, but may be refracted by a relatively low refractive index when passing through another position. As a result, the refraction angle of the light may vary depending on the position of the lens, and the display quality of the display device may be generally degraded.

For example, when a three-dimensional image is generated, the light may be refracted at a smaller refraction angle than the designed refraction angle due to the tilt of the optical member 200. When a two-dimensional image is generated, the light may be refracted instead of traveling straight due to the tilt of the optical member 200.

In view of the above, there is provided a means for addressing the problem of uneven display quality caused by the tilt of the lenses. For example, the problem of uneven display quality depending on the position of the lenses can be resolved by considering the longitudinal direction of the boundary of the lenses, the orientation of liquid crystals included in the lenses, and the linear polarization direction due to the polarization axis of light incident on the lenses.

Hereinafter, an ideal embodiment and a real embodiment are disclosed. The ideal embodiment relates to a display device that is theoretically implemented, whereas the real embodiment relates to a display device that is implemented in consideration of practical limitations of fabrication equipment, etc. Such practical limitations may include the limitation on changing the polarization direction as desired due to the polarization member in the display panel, the limitation on changing the orientation of the liquid crystals as desired due to cost constraints on fabrication equipment, etc.

FIG. 12 is a view showing a display device according to an embodiment of the present disclosure and polarization directions of lights in the display device, etc.

Referring to FIG. 12, in an embodiment, when a three-dimensional image is generated, the driving liquid crystals 254 may have a path PDY in the second linear polarization direction and may maintain the linear polarization direction of the incident light. The light passing through the driving liquid crystals 254 may still have (e.g., maintain) the path PDY in the second linear polarization direction.

A first plane INCLP represents an example of the linear polarization direction of incoming light INCL incident on the driving liquid crystals 254.

A second plane OGLP represents an example of the linear polarization direction of outgoing light OGL passing through the driving liquid crystals 254. The incoming light INCL may pass through the driving liquid crystals 254 to become the outgoing light OGL.

A third plane LMP represents an example of the alignment direction LMDR of the liquid crystal molecules LM in the lenses 231 and the linear polarization direction of the outgoing light OGL.

A fourth plane 231P represents an example of the longitudinal direction LBLDR of the boundary LBL between the lenses 231 and a linear polarization direction of the outgoing light OGL.

The polarizing member 257 may allow the light having the first polarization axis to pass through it. In an embodiment, the linear polarization direction by the first polarization axis may be a path PDY in the second linear polarization direction. Referring to the first plane INCLP and the coordinate system, the incoming light INCL may have a path PDY in the second linear polarization direction. The path PDY in the second linear polarization direction may be parallel to the second direction (e.g., the y-axis direction), but embodiments of the present disclosure are not necessarily limited thereto.

In an embodiment, as the linear polarization direction of light is maintained when a three-dimensional image is generated, with reference to the second plane OGLP and the coordinate system, the outgoing light OGL may have the path PDY in the second linear polarization direction. The embodiment shown in FIG. 12 relates to an ideal embodiment. The liquid crystal molecules LM are arranged such that they extend in the long-axis direction and the short-axis direction. The long-axis direction of the liquid crystal molecules LM may have a first refractive index (ne), and the short-axis direction of the liquid crystal molecules LM may have a second refractive index (no). According to an embodiment of the present disclosure, the first refractive index (ne) may be greater than the second refractive index (no). In an embodiment, the second refractive index (no) may be substantially equal to the refractive index of the filler layer 240, but embodiments of the present disclosure are not necessarily limited thereto.

According to an embodiment, the long-axis direction of the liquid crystal molecules LM may be parallel to the second direction (e.g., the y-axis direction), and the short-axis direction may be parallel to the first direction (e.g., the x-axis direction). Since the outgoing light OGL has the path PDY in the second linear polarization direction, and the path PDY in the second linear polarization direction is parallel to the second direction (e.g., the y-axis direction), the outgoing light OGL may undergo the first refractive index (ne) in the lens 231. Since the first refractive index (ne) is greater than the second refractive index (no) which is substantially equal to the refractive index of the filler layer 240, the outgoing light OGL that travels towards the filler layer 240 having a surface 240S that is in direct contact with the lenses 231 may be refracted.

According to an embodiment of the present disclosure, the longitudinal direction LBLDR of the boundary LBL between the lenses 231 may be parallel to the long-axis direction of the liquid crystal molecules LM. For example, in an embodiment the angle formed by them may be in a range from zero degrees to about 45 degrees.

According to an embodiment, the liquid crystal molecules LM may be oriented such that the long-axis direction is parallel to the linear polarization direction of the outgoing light OGL. In addition, the long-axis direction of the liquid crystal molecules LM may be parallel to the longitudinal direction LBLDR of the boundary LBL.

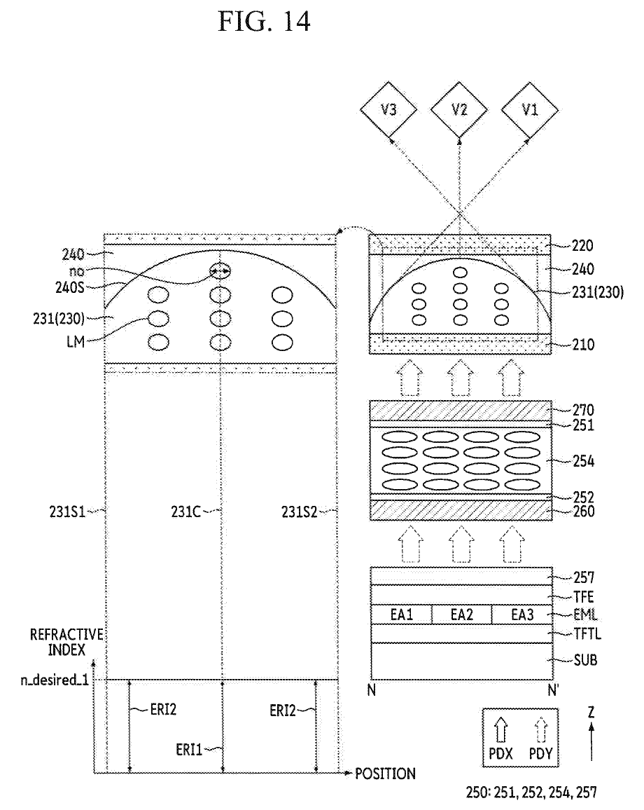

FIG. 13 is a plan view showing the longitudinal direction of the boundary between the lenses 231 and the orientation of liquid crystal molecules in the display device according to an embodiment of the present disclosure. FIG. 14 is a cross-sectional view taken along line N – N' of FIG. 13 when a three-dimensional image is generated.

Referring to FIGS. 13 and 14, according to an embodiment, the longitudinal direction LBLDR of the boundary LBL between adjacent lenses 231 may be parallel to the alignment direction LMDR of the liquid crystal molecules LM. In this instance, the angle formed by the longitudinal direction LBLDR of the boundary LBL and the alignment direction LMDR of the liquid crystal molecules LM may be zero degrees. The alignment direction LMDR of the liquid crystal molecules LM may be substantially coincident with the long-axis direction of the liquid crystal molecules LM. Accordingly, in an embodiment, the longitudinal direction LBLDR of the boundary LBL between adjacent lenses 231 may be parallel to the long-axis direction of the liquid crystal molecules LM.

The refraction angle of the outgoing light OGL is affected by the cross-sectional shape of the liquid crystal molecules LM through which the outgoing light OGL passes. The cross-sectional shape affecting the refraction angle of the outgoing light OGL may be the cross-section of the liquid crystal molecules LM in a cross-section of the lenses 231 taken in the longitudinal direction LBLDR of the boundary LBL. In the following descriptions, all cross-sectional views taken along the lines (e.g., N – N', R – R', T1 - T1', T2 - T2', etc.) are cross-sectional views cut in a direction perpendicular to the longitudinal direction LBLDR of the boundary LBL. In addition, the cross-sectional views taken along the lines may include the cross-sectional shape of the liquid crystal molecules LM in a cross-section of the lenses 231 taken in the longitudinal direction LBLDR of the boundary LBL.

According to an embodiment, the longitudinal direction LBLDR of the boundary LBL may be parallel to the long-axis direction of the liquid crystal molecules LM. Accordingly, when the cross-section of the lenses 231 is seen in the longitudinal direction LBLDR of the boundary LBL, the liquid crystal molecules LM may include a cross-section cut in the short-axis direction. In addition, the cross-sectional area of the liquid crystal molecules LM may be minimal.

The refractive index graph according to the position of the lenses 231 represents the effective refractive index measured along the direction perpendicular to the longitudinal direction LBLDR of the boundary LBL in the enlarged cross-sectional shape of the lens 231.

The refractive index refers to the refractive index of light measured when the outgoing light OGL passes through the lens 231 and the surface 240S of the filler layer 240. For example, the refractive index may be defined as the difference in refractive index between the lens 231 and the filler layer 240 at the surface 240S of the filler layer 240 that has the surface 240S that is in direct contact with the lens 231. Light is refracted at the surface 240S due to the difference in refractive index between the lens 231 and the filler layer 240, and the refraction angle may be derived by Snell’s Law.

As the effective refractive index is defined by the difference in refractive index between the lens 231 and the filler layer 240, the effective refractive index may have a positive or negative correlation with the refraction angle. For example, in an embodiment the effective refractive index may have a positive correlation with the refraction angle. It should be understood, however, that embodiments of the present disclosure are not necessarily limited thereto.

The increase in the effective refractive index means that the difference in the refractive index between the lens 231 and the filler layer 240 increases, and therefore the refraction angle at the surface 240S may increase by Snell's law. The decrease in the effective refractive index means that the difference in the refractive index between the lens 231 and the filler layer 240 decreases, and therefore the refraction angle at the surface 240S may decrease by Snell's law.

The embodiment shown in FIG. 14 relates to an ideal embodiment. The cross-sectional area of the liquid crystal molecules LM in a cross-section of the lens 231 taken from the longitudinal direction LBLDR of the boundary LBL may be minimal. In this instance, the difference in refractive index between the lens 231 and the filler layer 240 at a portion of the surface 240S overlapping a center 231C of the lens 231 may be the first effective refractive index ERI1. In addition, the difference in refractive index between the lens 231 and the filler layer 240 at a portion of the surface 240S overlapping side surfaces 231S1 and 231S2 of the lens 231 may be a second effective refractive index ERI2. According to an embodiment, the cross-sectional area of the liquid crystal molecules LM is minimal, and the difference in refractive index between the filler layer 240 and the lens 231 may be the same across the surface 240S regardless of the position. Accordingly, the first effective refractive index ERI1 and the second effective refractive index ERI2 may be equal to a first value n_desired_1 desired by an operator. As described above, since the outgoing light OGL has a linear polarization direction parallel to the long-axis direction of the liquid crystals, and the long-axis direction of the liquid crystals is the first refractive index (ne), the first effective refractive index ERI1 may be equal to a difference between the first refractive index (ne) and the refractive index of the filler layer 240. According to an embodiment of the present disclosure, since the refractive index of the filler layer 240 is equal to the second refractive index (no) which is the refractive index in the short-axis direction of the liquid crystals, the first effective refractive index ERI1 may be equal to the difference between the first refractive index (ne) and the second refractive index (no). It should be understood, however, that embodiments of the present disclosure are not necessarily limited thereto. When a three-dimensional image is generated, light may be refracted with a relatively large refraction angle, and at this time, the refractive index in the lens 231 that the light undergoes may be the first refractive index (ne), and the refractive index in the filler layer 240 may be the second refractive index (no).

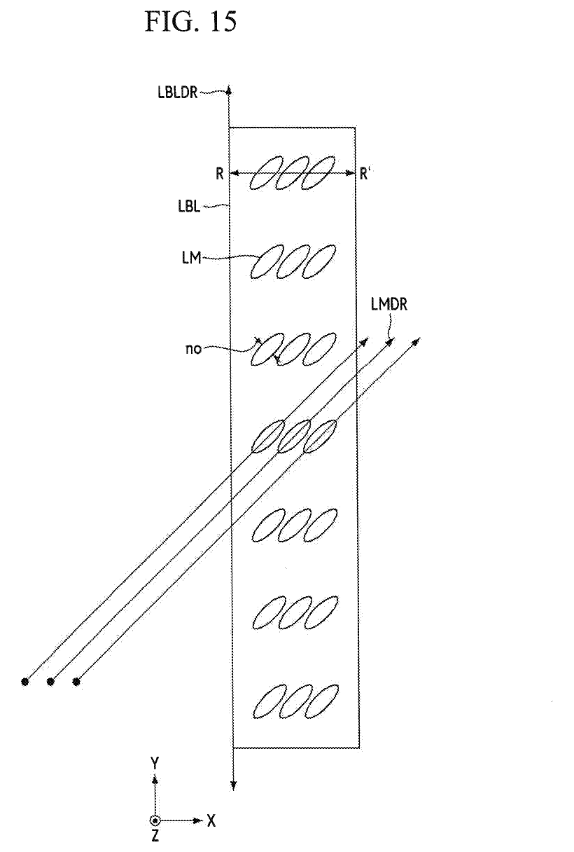

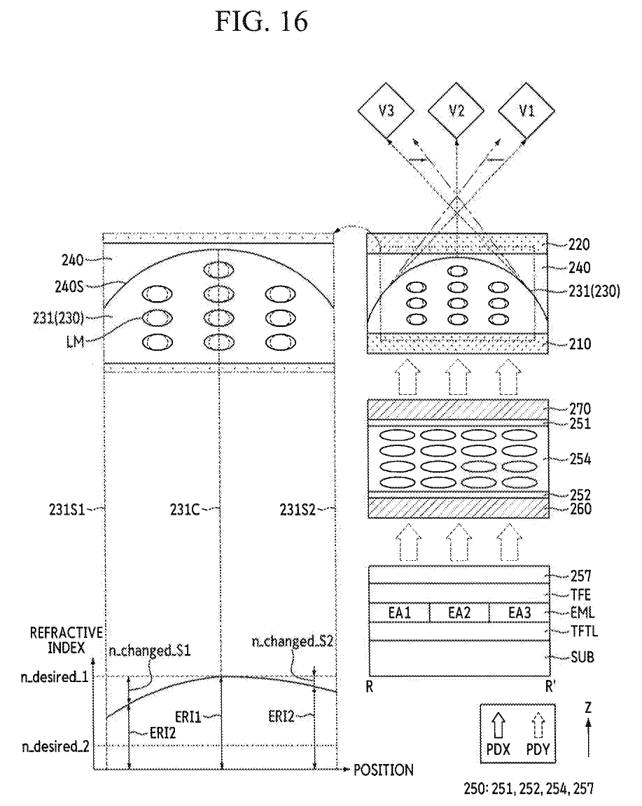

FIG. 15 is a plan view showing the longitudinal direction of the boundary and the orientation of liquid crystal molecules in the display device according to an embodiment of the present disclosure. FIG. 16 is a cross-sectional view taken along line R – R' of FIG. 15 when a three-dimensional image is generated.

Referring to FIGS. 15 and 16, according to an embodiment, the longitudinal direction LBLDR of the boundary LBL between adjacent lenses 231 may not be parallel to the alignment direction LMDR of the liquid crystal molecules LM. In this instance, the angle formed by the longitudinal direction LBLDR of the boundary LBL and the alignment direction LMDR of the liquid crystal molecules LM may be greater than zero degrees. The alignment direction LMDR of the liquid crystal molecules LM may not be parallel to the long-axis direction of the liquid crystal molecules LM.

According to an embodiment, unlike a prior embodiment, the alignment direction LMDR of the liquid crystal molecules LM is not parallel to the longitudinal direction LBLDR of the boundary LBL. Considering the rubbing process that determines the alignment direction LMDR and the process of tilting the lens 231 to prevent a moiré pattern, the alignment direction LMDR of the liquid crystal molecules LM may exceed zero degrees with the longitudinal direction LBLDR of the boundary LBL.

When the longitudinal direction LBLDR of the boundary LBL and the alignment direction LMDR of the liquid crystal molecules LM form an angle exceeding zero degrees, the cross-sectional area of the liquid crystal molecules LM in a cross-section of the lens 231 taken from the longitudinal direction LBLDR of the boundary LBL may increase.

For example, since the alignment direction LMDR of the liquid crystal molecules LM is parallel to the long-axis direction of the liquid crystals, as the angle formed by the longitudinal direction LBLDR of the boundary LBL and the long-axis direction of the liquid crystal molecules LM increases, the cross-sectional area of the liquid crystal molecules LM in a cross-section of the lens 231 taken from the longitudinal direction LBLDR of the boundary LBL can increase. Alternatively, as the angle formed by the longitudinal direction LBLDR of the boundary LBL and the long-axis direction of the liquid crystal molecules LM decreases, the cross-sectional area of the liquid crystal molecules LM in the cross-section of the lens 231 taken from the longitudinal direction LBLDR of the boundary LBL may decrease.

When the cross-sectional area of the liquid crystal molecules LM increases, the effective refractive index may change non-uniformly depending on the position of the lens 231. The difference in refractive index between the lens 231 and the filler layer 240 at the surface 240S including the center 231C of the lens 231 may be the first effective refractive index ERI1. The difference in refractive index between the lens 231 and the filler layer 240 at the surface 240S including side surfaces 231S1 and 231S2 of the lens 231 may be the second effective refractive index ERI2. The second effective refractive index ERI2 may decrease with a difference from the first effective refractive index ERI1 by a first change amount n_changed_S1 or a second change amount n_changed_S2. Unlike a prior embodiment, as the angle formed by the longitudinal direction LBLDR of the boundary LBL and the long-axis direction (or the alignment direction LMDR) of the liquid crystal molecules LM increases, the difference between the first effective refractive index ERI1 and the second effective refractive index ERI2 may increase.

Since the refractive index changes from the center 231C of the lens 231 to the side surfaces 231S1 and 231S2, the refraction angle of the outgoing light OGL may also change. As the second effective refractive index ERI2 decreases, the refraction angle of the outgoing light OGL may also decrease, and the light exiting from the surface 240S may not be refracted to the viewing angle desired by the operator.

Herein, there is provided a solution to the problem of the decrease in the effective refractive index due to the cross-sectional area of the liquid crystal molecules LM increased by the angle between the longitudinal direction LBLDR of the tilted boundary LBL and the alignment direction LMDR of the liquid crystal molecules LM. As the cross-sectional area of the liquid crystal molecules LM increases, the refraction angle of light passing through the surface 240S also changes, and the display quality of the display device may deteriorate. In an embodiment shown in FIG. 15, only the alignment direction LMDR of the liquid crystal molecules LM is considered, and the longitudinal direction LBLDR of the boundary LBL is not tilted.

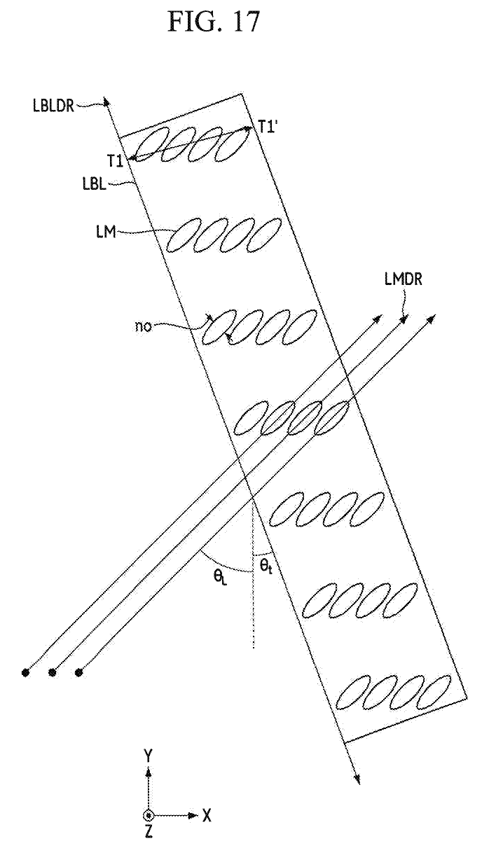

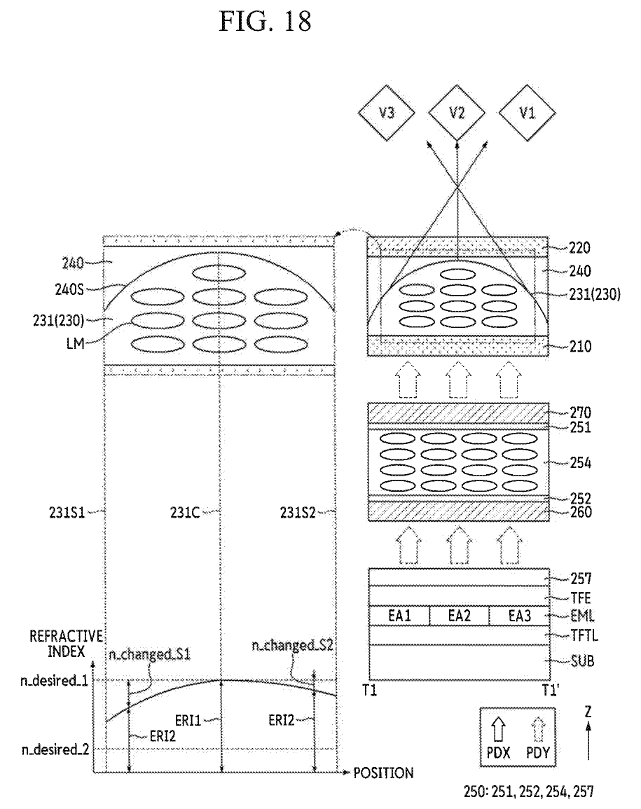

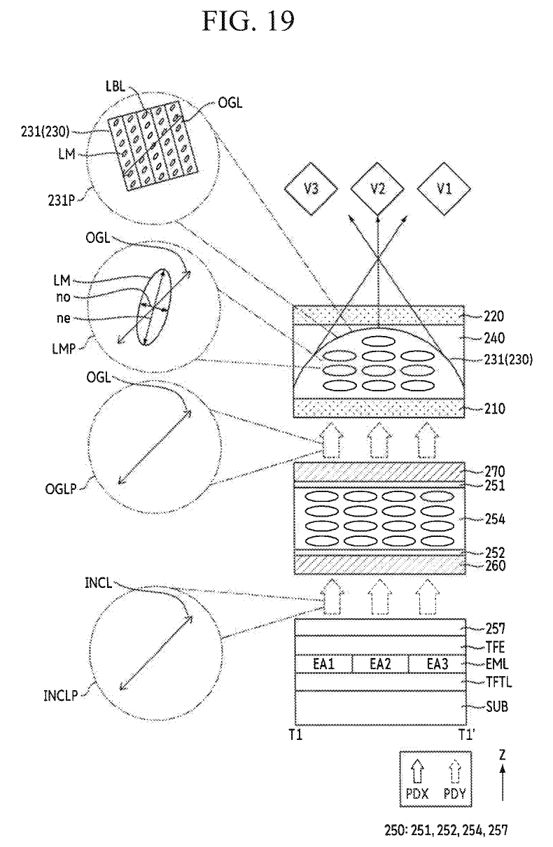

FIG. 17 is a plan view showing the longitudinal direction of the boundary and the alignment direction of liquid crystal molecules in a display device according to Comparative Example 1. FIG. 18 is a cross-sectional view taken along line T1 – T1' of FIG. 17 when a three-dimensional image is generated. FIG. 19 is a view showing a display device according to Comparative Example 1 and polarization directions of lights in the display device, etc.

Referring to FIGS. 17 to 19, in Comparative Example 1, the angle formed by the longitudinal direction LBLDR of the boundary LBL of the adjacent lenses 231 and the alignment direction LMDR may exceed about 45 degrees. In practice, the alignment direction LMDR of the liquid crystals may be fixed without change due to the characteristics of the fabrication equipment. Accordingly, the alignment direction LMDR may be fixed to a first angle θ_{L}, for example. In an embodiment, the first angle θ_{L} may be, but is not necessarily limited to, about 45 degrees.

When the longitudinal direction LBLDR of the boundary LBL is formed so that the angle formed by the longitudinal direction LBLDR of the boundary LBL and the alignment direction LMDR exceeds the first angle θ_{L}, the cross-sectional area of the liquid crystal molecules LM may be relatively large.

Since the cross-sectional area of the liquid crystal molecules LM is relatively large, the difference between the second effective refractive index ERI2 and the first effective refractive index ERI1 is relatively large, and therefore, the refraction angle of light passing through the surface 240S may change relatively greatly.

The polarizing member 257 placed on the display panel may allow the light having the first polarization axis to pass through it. The light that passes through the polarizing member 257 may be polarized in a linear polarization direction by the first polarization axis.

In an embodiment, the first polarization axis may be fixed without changing due to the characteristics of the fabrication equipment. Accordingly, the linear polarization direction of the light (or incoming light INCL) output from the polarizing member 257 cannot be arbitrarily changed. If the polarizing member 257 is not fabricated directly (e.g., custom manufactured) but purchased from an external source, the first polarization axis cannot be arbitrarily changed as described above.

If the cross-sectional area of the liquid crystal molecules LM is relatively large, the linear polarization direction of the outgoing light OGL may not be coincident with the long-axis direction of the liquid crystal molecules LM. Referring to an embodiment described above with reference to FIGS. 12-14, if the linear polarization direction of the outgoing light OGL coincides with the long-axis direction of the liquid crystal molecules LM, the outgoing light OGL undergoes the first refractive index (ne) in the long-axis direction and is refracted at the surface 240S of the filler layer 240.

The long-axis direction and the short-axis direction of the liquid crystal molecules LM are affected by the cross-sectional area of the liquid crystal molecules LM.

Even though the alignment direction LMDR of the liquid crystal molecules LM is fixed, if the longitudinal direction LBLDR of the boundary LBL is tilted, the cross-sectional area of the liquid crystal molecules LM in the cross-section of the lens 231 taken in the longitudinal direction LBLDR of the boundary LBL may change.

Accordingly, depending on the angle formed by the longitudinal direction LBLDR of the boundary LBL and the alignment direction LMDR, the long-axis direction and the short-axis direction of the liquid crystal molecules LM, which determine the refractive index of the outgoing light OGL, change relatively. However, the alignment direction LMDR of the liquid crystal molecules LM does not change due to the characteristics of the fabrication equipment in the fabrication process. Even though the alignment direction LMDR of the liquid crystal molecules LM does not change, the long-axis direction and the short-axis direction of the liquid crystal molecules LM, which determine the refractive index of the outgoing light OGL, change relatively, depending on the angle formed by the longitudinal direction LBLDR of the boundary LBL and the alignment direction LMDR, While an embodiment shown in FIGS. 12-14 is an embodiment in which the alignment direction LMDR is parallel to the long-axis direction, when the alignment direction LMDR of the liquid crystal molecules LM and the longitudinal direction LBLDR of the boundary LBL form an angle, the long-axis direction and the short-axis direction are determined by considering the cross-sectional area of the liquid crystal molecules LM.

Additionally, the outgoing light OGL undergoes a refractive index by comparing its linear polarization direction with the changed long-axis direction (or short-axis direction).

The refraction angle of the outgoing light OGL is determined by Snell's law according to the difference between the refractive index and the refractive index of the filling layer 240.

While the linear polarization direction of the outgoing light OGL and the alignment direction LMDR of the liquid crystal molecules LM cannot be changed due to the characteristics of the fabrication equipment, the long-axis direction changes as the longitudinal direction LBLDR of the boundary LBL is tilted, so that the refraction angle of the outgoing light OGL also changes.

When the cross-sectional area of the liquid crystal molecules LM is relatively large, the refraction angle changes with a relatively large change from the normal value. When the cross-sectional area of the liquid crystal molecules LM is relatively small, the refraction angle changes with a relatively small change from the normal value.

If the amount of change in the refraction angle is large, the refraction angle may fail to reach the target value, etc., which may lower the luminance in a three-dimensional image and degrade the color gamut.

In view of the above, according to embodiments of the present disclosure, the cross-sectional area of liquid crystal molecules LM is formed relatively small when a three-dimensional image is provided, so that image luminance is increased and light leakage is prevented. As a result, the display quality of the display device can be increased.

Again, when the longitudinal direction LBLDR of the boundary LBL is formed so that the angle formed by the longitudinal direction LBLDR of the boundary LBL and the alignment direction LMDR exceeds 45 degrees, the cross-sectional area of the liquid crystal molecules LM may be relatively large. Therefore, the difference between the second effective refractive index ERI2 and the first effective refractive index ERI1 may be relatively large.

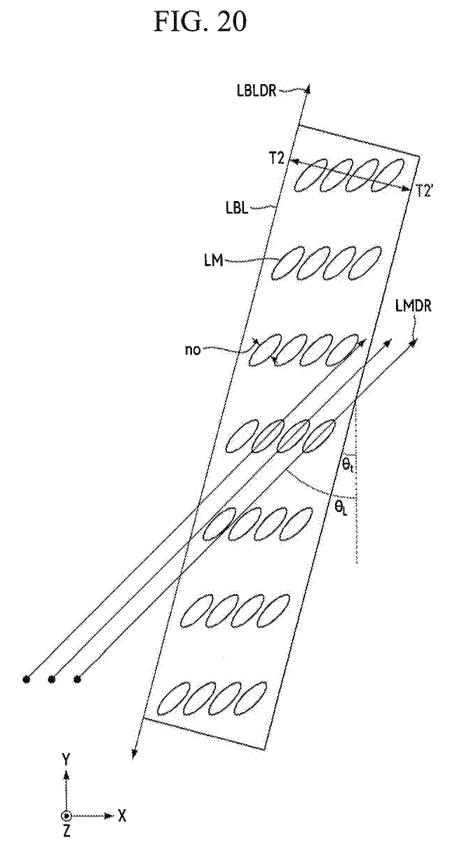

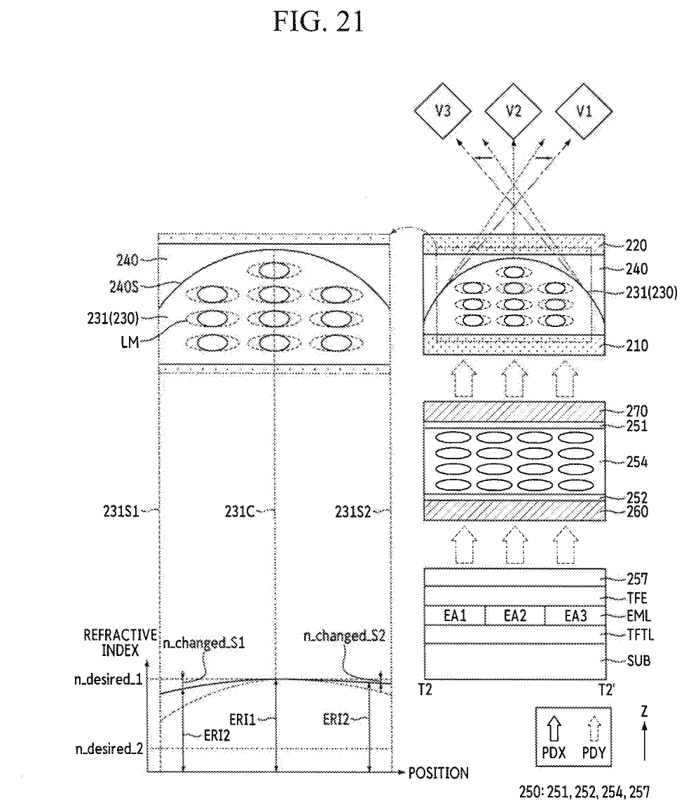

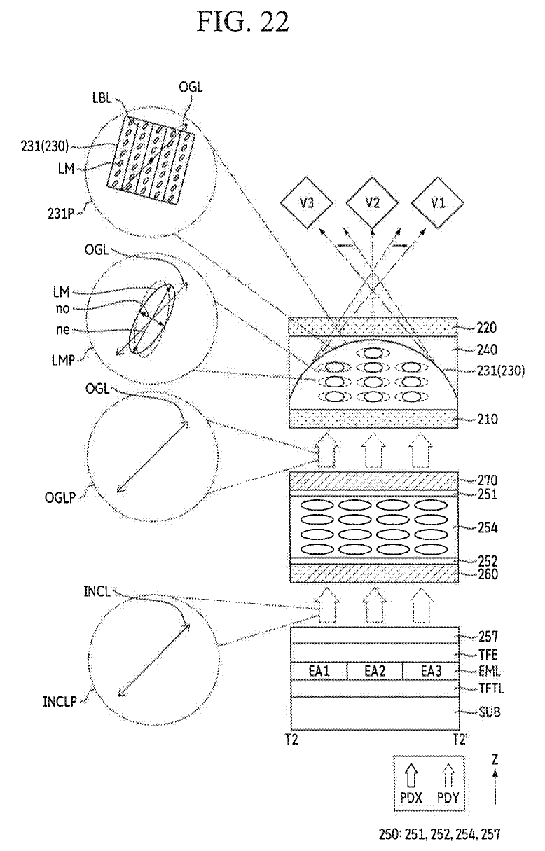

FIG. 20 is a plan view showing the longitudinal direction of the boundary and the orientation of liquid crystal molecules in the display device according to an embodiment of the present disclosure. FIG. 21 is a cross-sectional view taken along line T2 – T2' of FIG. 20 when a three-dimensional image is generated. FIG. 22 is a view showing a display device according to an embodiment of the present disclosure and polarization directions of lights in the display device, etc.

Referring to FIGS. 20 to 22, in an embodiment, the angle formed by the longitudinal direction LBLDR of the boundary LBL and the alignment direction LMDR may be greater than zero degrees and less than or equal to about 45 degrees. In practice, the alignment direction LMDR of the liquid crystals may be fixed without change due to the characteristics of the fabrication equipment. Accordingly, the alignment direction LMDR may be fixed to a first angle θ_{L}, for example. The first angle θ_{L} may be, but is not necessarily limited to, about 45 degrees.

When the longitudinal direction LBLDR of the boundary LBL is formed so that the angle formed by the longitudinal direction LBLDR of the boundary LBL and the alignment direction LMDR does not exceed the first angle θ_{L}, the cross-sectional area of the liquid crystal molecules LM may be relatively small. Therefore, the difference between the second effective refractive index ERI2 and the first effective refractive index ERI1 may be relatively small. According to embodiments of the present disclosure, the cross-sectional area of liquid crystal molecules LM is formed relatively small when a three-dimensional image is provided, so that image luminance is increased. As a result, the display quality of the display device can be increased.

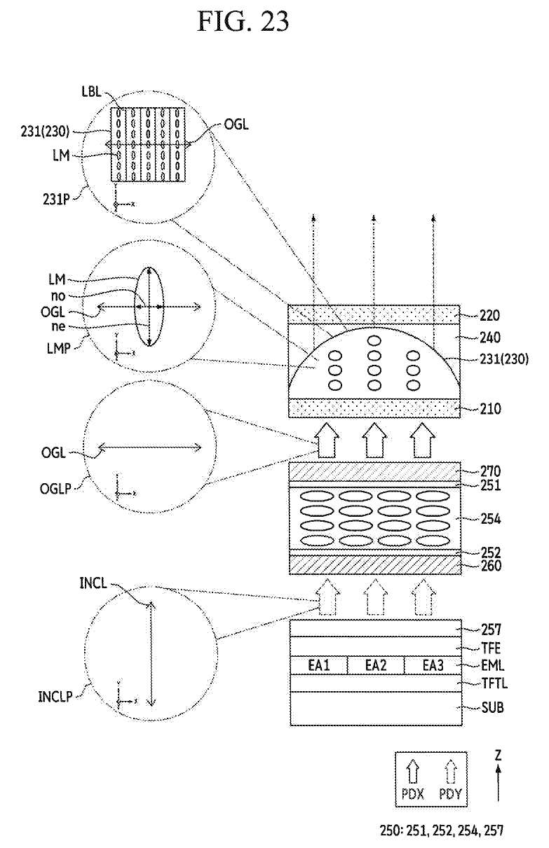

FIG. 23 is a view showing a display device according to an embodiment of the present disclosure and polarization directions of lights in the display device, etc.

Referring to FIG. 23, when a two-dimensional image is generated, the driving liquid crystals 254 may have a path PDY in the second linear polarization direction and may change the linear polarization direction of the incident light. The light passing through the driving liquid crystals 254 may have the path PDX in the first linear polarization direction.

As the linear polarization direction of light is changed when a two-dimensional image is generated, with reference to the second plane OGLP and the coordinate system, the outgoing light OGL may have the path PDX in the first linear polarization direction. The embodiment shown relates to an ideal embodiment. The long-axis direction of the liquid crystal molecules LM may have a first refractive index (ne), and the short-axis direction of the liquid crystal molecules LM may have a second refractive index (no). According to an embodiment of the present disclosure, the first refractive index (ne) may be greater than the second refractive index (no). The second refractive index (no) may be substantially equal to the refractive index of the filler layer 240, but embodiments of the present disclosure are not necessarily limited thereto.

According to an embodiment, the long-axis direction of the liquid crystal molecules LM may be parallel to the second direction (e.g., the y-axis direction), and the short-axis direction may be parallel to the first direction (e.g., the x-axis direction). Since the outgoing light OGL has the path PDX in the first linear polarization direction, and the path PDX in the first linear polarization direction is parallel to the first direction (e.g., the x-axis direction), the outgoing light OGL may undergo the second refractive index (no) in the lens 231. Since the second refractive index (no) is substantially equal to the refractive index of the filler layer 240, the outgoing light OGL that travels towards the filler layer 240 having a surface 240S that is in direct contact with the lens 231 may travel straight.

According to an embodiment of the present disclosure, the linear polarization direction of the outgoing light OGL may be parallel to the short-axis direction of the liquid crystal molecules LM. For example, the angle formed by them may be zero degrees.

According to an embodiment, the liquid crystal molecules LM may be oriented such that the short-axis direction is parallel to the linear polarization direction of the outgoing light OGL.

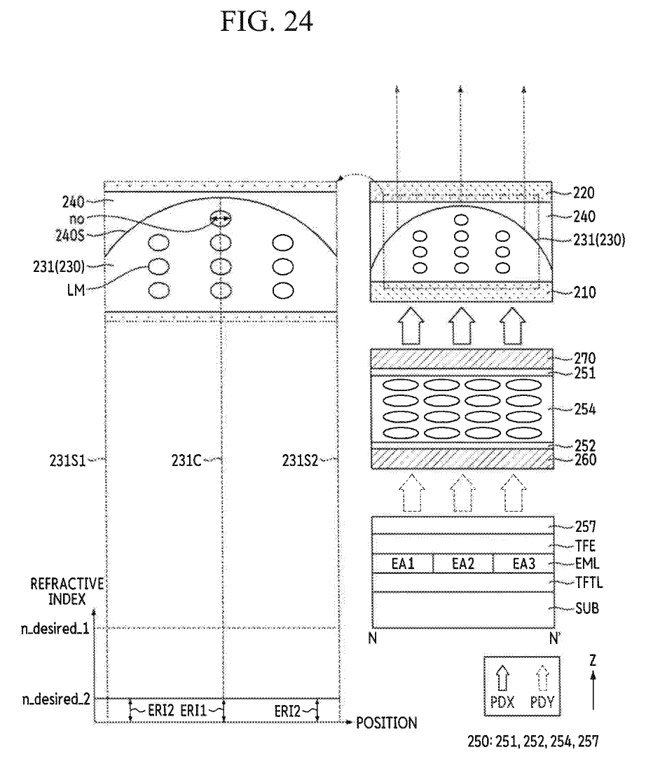

FIG. 24 is a cross-sectional view taken along line N – N' of FIG. 13 when a two-dimensional image is generated.

Referring to FIG. 24, according to an embodiment, the longitudinal direction LBLDR of the boundary LBL between adjacent lenses 231 may be parallel to the long-axis direction of the liquid crystal molecules LM. Accordingly, when the cross-section of the lenses 231 is seen in the longitudinal direction LBLDR of the boundary LBL, the liquid crystal molecules LM may include a cross-section cut in the short-axis direction. In addition, the cross-sectional area of the liquid crystal molecules LM may be minimal.

The embodiment shown relates to an ideal embodiment. The cross-sectional area of the liquid crystal molecules LM in the cross-section of the lens 231 taken in the longitudinal direction LBLDR of the boundary LBL may be minimal. In this instance, the difference in refractive index between the lens 231 and the filler layer 240 at a portion of the surface 240S overlapping a center 231C of the lens 231 may be the first effective refractive index ERI1. In addition, the difference in refractive index between the lens 231 and the filler layer 240 at a portion of the surface 240S overlapping side surfaces 231S1 and 231S2 of the lens 231 may be a second effective refractive index ERI2. According to an embodiment, the cross-sectional area of the liquid crystal molecules LM is minimal, and the difference in refractive index between the filler layer 240 and the lens 231 may be the same across the surface 240S regardless of the position. Accordingly, the first effective refractive index ERI1 and the second effective refractive index ERI2 may be equal to a second value n_desired_2 desired by an operator. As described above, since the outgoing light OGL has a linear polarization direction parallel to the short-axis direction of the liquid crystals, and the short-axis direction of the liquid crystals is the second refractive index (no), the first effective refractive index ERI1 may be equal to a difference between the second refractive index (no) and the refractive index of the filler layer 240. According to an embodiment of the present disclosure, since the refractive index of the filler layer 240 is equal to the second refractive index (no) which is the refractive index in the short-axis direction of the liquid crystals, the first effective refractive index ERI1 may be equal to the difference between the second refractive index (no) and the second refractive index (no). It should be understood, however, that embodiments of the present disclosure are not necessarily limited thereto. When a three-dimensional image is generated, light may be refracted with a relatively large refraction angle, and at this time, the refractive index in the lens 231 that the light undergoes may be the first refractive index (ne), and the refractive index in the filler layer 240 may be the second refractive index (no). In an embodiment, the linear polarization direction of the incoming light INCL and the linear polarization direction of the outgoing light OGL in the first plane INCLP and the second plane OGLP may be orthogonal to each other.

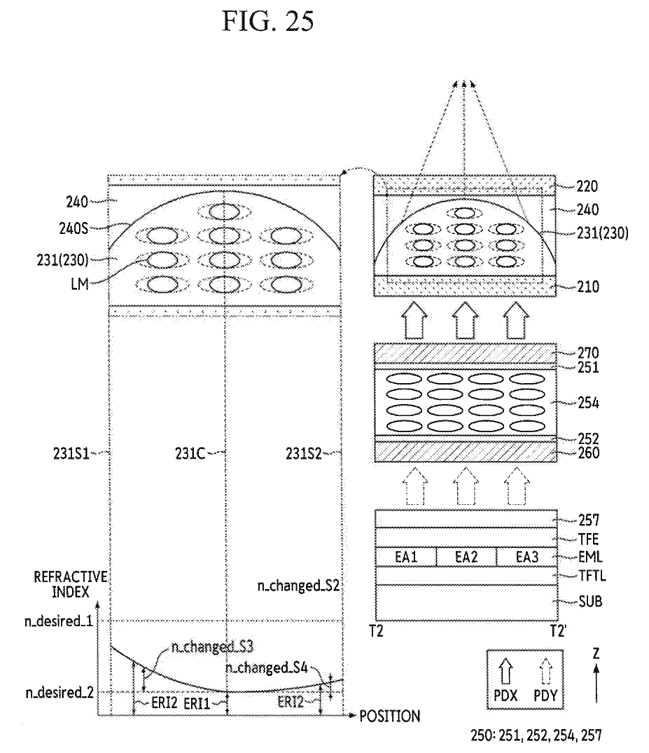

FIG. 25 is a cross-sectional view taken along line T2 – T2' of FIG. 20 when a two-dimensional image is generated.

Referring to FIG. 25, the cross-sectional area of the liquid crystal molecules LM may be larger than that of a previously described embodiment. When the cross-sectional area of the liquid crystal molecules LM increases, the effective refractive index may change non-uniformly depending on the position of the lens 231. The difference in refractive index between the lens 231 and the filler layer 240 at the surface 240S including the center 231C of the lens 231 may be the first effective refractive index ERI1. The difference in refractive index between the lens 231 and the filler layer 240 at the surface 240S including side surfaces 231S1 and 231S2 of the lens 231 may be the second effective refractive index ERI2. The second effective refractive index ERI2 may increase with a difference from the first effective refractive index ERI1 by a third change amount n_changed_S3 or a fourth change amount n_changed_S4. Unlike a prior embodiment, as the angle formed by the longitudinal direction LBLDR of the boundary LBL and the long-axis direction (or the alignment direction LMDR) of the liquid crystal molecules LM increases, the difference between the first effective refractive index ERI1 and the second effective refractive index ERI2 may increase.

When a two-dimensional image is generated, the linear polarization direction of the incoming light INCL is converted while passing through the driving liquid crystals 254. The light incident on the first base substrate 210 has a second polarization axis. The linear polarization direction by the second polarization axis may be different from the linear polarization direction by the first polarization axis.

Compared to the ideal embodiment, even if the cross-sectional area of the liquid crystal molecules LM is substantially increased, by adjusting the angle of the direction converted by the driving liquid crystals 254, the short-axis direction of the liquid crystal molecules LM can be coincident with the linear polarization direction of the outgoing light OGL. According to an embodiment of the present disclosure, the angle formed by the short-axis direction of the liquid crystal molecules LM and the linear polarization direction by the second polarization axis may be zero degrees. The linear polarization direction of the outgoing light OGL and the linear polarization direction of the incoming light INCL are different from those of the same three-dimensional image.

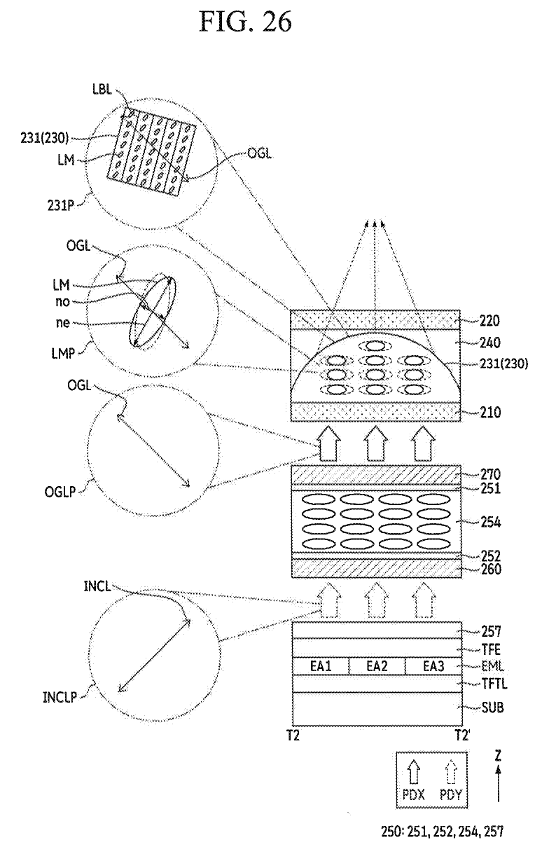

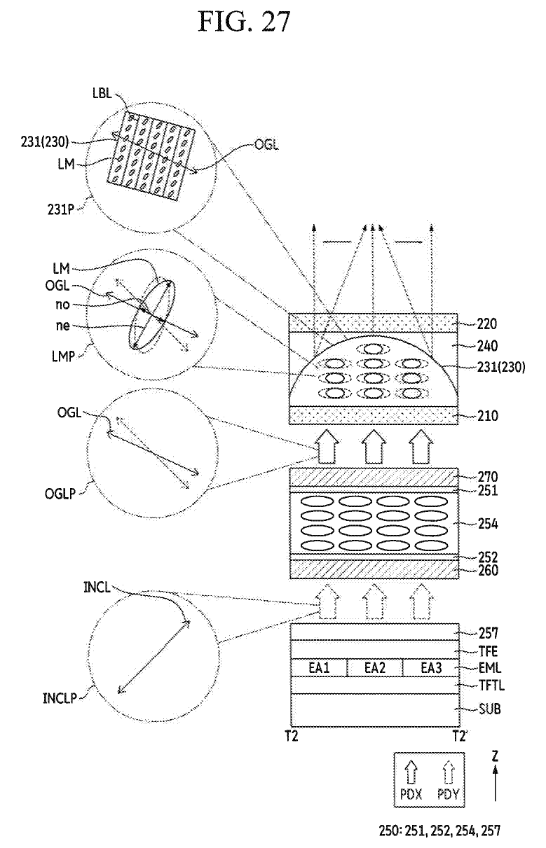

FIG. 26 is a view for illustrating by comparison the longitudinal direction of the boundary, the polarization direction of light, the alignment direction of liquid crystal molecules, etc. in the display device according to Comparative Example 2. FIG. 27 is a view for illustrating by comparison the longitudinal direction of the boundary, the polarization direction of light, the alignment direction of liquid crystal molecules, etc. in the display device according to an embodiment of the present disclosure.

Referring to FIG. 26, the linear polarization direction of the incoming light INCL and the linear polarization direction of the outgoing light OGL in the first plane INCLP and the second plane OGLP may be orthogonal to each other as in a prior embodiment. However, since the cross-sectional area of the liquid crystal molecules LM is relatively large, unlike in the first embodiment, when a two-dimensional image is generated, the linear polarization direction of the outgoing light OGL and the linear polarization direction of the incoming light INCL may be formed such that they are not orthogonal to each other.

Referring to FIG. 27, the linear polarization direction of the outgoing light OGL may form an acute or obtuse angle with the linear polarization direction of the incoming light INCL. According to embodiments of the present disclosure, to generate a two-dimensional image when the linear polarization direction of the outgoing light OGL is changed, the linear polarization direction of the outgoing light OGL forms an acute or obtuse angle with the linear polarization direction of the incoming light INCL according to the changed cross-sectional area of the liquid crystal molecules LM, thereby suppressing image distortion or light leakage of the display device.

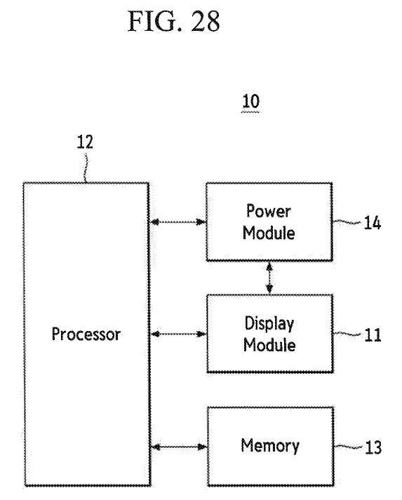

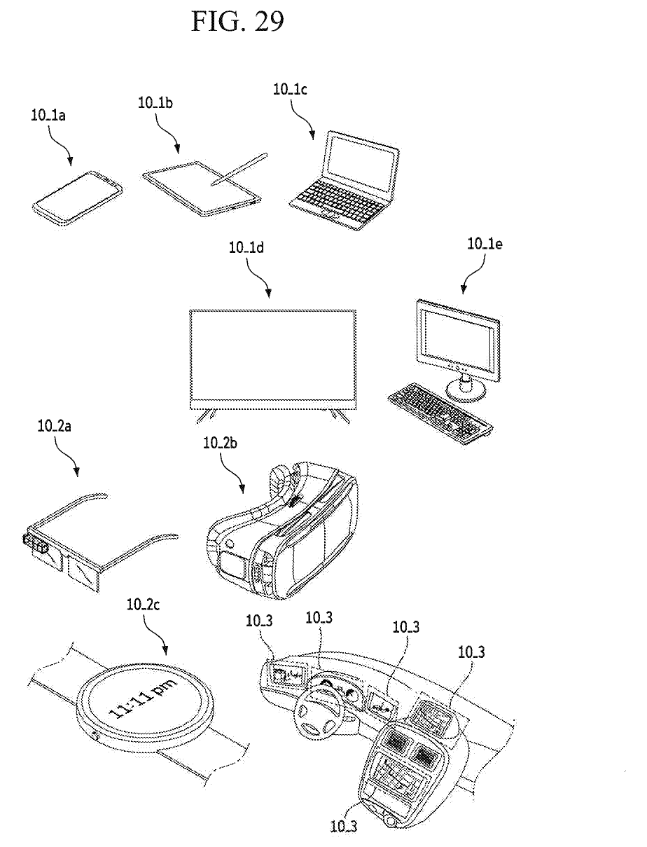

FIG. 28 is a block diagram of an electronic device according to an embodiment of the present disclosure. FIG. 29 is a view showing electronic devices according to a variety of embodiments of the present disclosure.

Referring to FIG. 28, an electronic device 10 according to an embodiment of the present disclosure may include a display module 11, a processor 12, a memory 13, and a power module 14. The display module 11 may be identical to the above-described display module 100 of FIG. 1.

The processor 12 may include at least one of: a central processing unit (CPU), an application processor (AP), a graphic processing unit (GPU), a communication processor (CP), an image signal processor (ISP), and a controller.

The memory 15 may store data information required for the operation of the processor 12 or the display module 11. When the processor 12 executes an application stored in the memory 15, an image data signal and/or an input control signal may be transmitted to the display module 11. The display module 11 may process the received signal and output image information through a display screen.

The power module 14 may include a power supply module such as a power adapter and a battery device. The power module 14 may include a power conversion module. The power conversion module may convert power supplied by the power supply module to generate power required for the operation of the electronic device 10.

At least one of the elements of the electronic device 10 described above may be included in the display devices according to embodiments described above. In addition, some of the individual modules functioning as a single module may be included in the display device while some others may be provided separately from the display device. For example, the display device may include the display module 11, and the processor 12, the memory 13 and the power module 14 may be implemented as other devices inside the electronic device instead of the display device.

Referring to FIG. 29, a variety of electronic devices employing the display devices according to embodiments of the present disclosure may include electronic devices for displaying images, such as a smartphone 10_1a, a tablet PC 10_1b, a laptop computer 10_1c, a TV 10_1d, and a desktop monitor 10_1e. In addition, a variety of electronic devices employing the display devices according to embodiments of the present disclosure may include wearable electronic devices including display modules such as smart glasses 10_2a, a head-mounted display 10_2b and a smart watch 10_2c, and electronic devices for vehicles 10_3 including display modules such as a center information display (CID) placed on the instrument cluster, the center fascia and the dashboard of a vehicle, and a room mirror display, etc.

Although embodiments of the disclosure have been described above with reference to the accompanying drawings, it will be understood by those having ordinary skill in the technical field to which the disclosure belongs that the present disclosure may be practiced in other specific forms without altering the technical idea or essential features of the disclosure. It should therefore be understood that embodiments described above are examples in all respects and are not intended to be limiting.

What is claimed is:

1. A display device comprising:
a display panel;
a first base substrate arranged on the display panel;
a second base substrate arranged on the first base substrate; and
a plurality of lenses arranged between the first base substrate and the second base substrate, comprising liquid crystal molecules having a long-axis and a short-axis, the plurality of lenses is spaced apart from one another with a boundary between them,
wherein the boundary extends in a longitudinal direction,
wherein the liquid crystal molecules are oriented in a long-axis direction of the liquid crystal molecules, and
wherein an angle formed by the longitudinal direction of the boundary and the long-axis direction of the liquid crystal molecules is in a range of zero degrees to about 45 degrees.

2. The display device of claim 1, wherein the angle formed by the longitudinal direction of the boundary and the long-axis direction of the liquid crystal molecules is in a range of zero degrees to about 45 degrees.

3. The display device of claim 2, wherein the angle formed by the longitudinal direction of the boundary and the long-axis direction of the liquid crystal molecules is zero degrees.

4. The display device of claim 1, further comprising:
a polarizing member located between the display panel and the first base substrate, the polarizing member transmitting light having a first polarization axis,
wherein light incident from the display panel to the first base substrate when a three-dimensional image is generated has the first polarization axis, and
wherein an angle formed by the long-axis direction of the liquid crystal molecules and a linear polarization direction by the first polarization axis is in a range of zero degrees to about 45 degrees.

5. The display device of claim 1, wherein a cross-sectional area of the liquid crystal molecules in a cross-section of the plurality of lenses taken from the longitudinal direction of the boundary decreases as the angle formed by the longitudinal direction of the boundary and the long-axis direction of the liquid crystal molecules decreases.

6. The display device of claim 1, further comprising:
a filler layer arranged between the first base substrate and the second base substrate, the filler layer having a surface in direct contact with the plurality of lenses; and
a polarizing member arranged between the display panel and the first base substrate, the polarizing member transmitting light having a first polarization axis,
wherein a difference between a refractive index of the plurality of lenses and a refractive index of the filler layer at a portion of the surface overlapping a center of a lens of the plurality of lenses is a first effective refractive index,
wherein a difference between the refractive index of the plurality of lenses and the refractive index of the filler layer at a portion of the surface overlapping a side surface of the lens is a second effective refractive index, and
wherein a difference between the first effective refractive index and the second effective refractive index increases as the angle formed by the longitudinal direction of the boundary and the long-axis direction of the liquid crystal molecules increases.

7. The display device of claim 6, wherein a refraction angle of light passing through the portion of the surface overlapping the side surface of the lens decreases as the second effective refractive index decreases.

8. The display device of claim 6, wherein the first effective refractive index is greater than the second effective refractive index.

9. The display device of claim 6, wherein:
the second effective refractive index increases as a cross-sectional area of the liquid crystal molecules decreases; and
the cross-sectional area of the liquid crystal molecules is in a cross-section of the lens taken in the longitudinal direction of the boundary.

10. The display device of claim 9, wherein a difference between the first effective refractive index and the second effective refractive index decreases as the cross-sectional area of the liquid crystal molecules in a cross-section of the lens taken in the longitudinal direction of the boundary decreases.

11. The display device of claim 4, wherein:
light incident from the display panel to the first base substrate has a second polarization axis when a two-dimensional image is generated; and
the linear polarization direction by the first polarization axis is different from a linear polarization direction by the second polarization axis.

12. The display device of claim 11, wherein an angle formed by a short-axis direction of the liquid crystal molecules and the linear polarization direction by the second polarization axis is zero degrees.

13. The display device of claim 12, further comprising:
a third base substrate arranged between the polarizing member and the first base substrate;
a fourth base substrate arranged between the third base substrate and the first base substrate; and
driving liquid crystals arranged between the third base substrate and the fourth base substrate,
wherein light incident from the display panel on the driving liquid crystals has the first polarization axis, and
wherein light incident from the driving liquid crystals onto the third base substrate has the second polarization axis when the two-dimensional image is generated.

14. The display device of claim 11, wherein the linear polarization direction by the first polarization axis forms an acute or obtuse angle with the linear polarization direction by the second polarization axis.

15. The display device of claim 13, further comprising:
a first driving electrode disposed between the driving liquid crystals and the fourth base substrate; and
a second driving electrode disposed between the third base substrate and the driving liquid crystals.

16. An electronic device comprising:
a processor configured to provide an image signal;
a display module configured to receive the image signal from the processor to display an image; and
a power module configured to supply power to the display module,
wherein the display module comprises:
a display panel;
a first base substrate arranged on the display panel;
a second base substrate arranged on the first base substrate; and
a plurality of lenses arranged between the first base substrate and the second base substrate, comprising liquid crystal molecules having a long-axis and a short-axis, the plurality of lenses is spaced apart from one another with a boundary between them,
wherein the boundary extends in a longitudinal direction, wherein the liquid crystal molecules are oriented in a long-axis direction of the liquid crystal molecules, and
wherein an angle formed by the longitudinal direction of the boundary and the long-axis direction of the liquid crystal molecules is in a range of zero degrees to about 45 degrees.

17. The electronic device of claim 16, wherein the angle formed by the longitudinal direction of the boundary and the long-axis direction of the liquid crystal molecules is in a range of zero degrees to about 45 degrees.

18. The electronic device of claim 16, further comprising:
a polarizing member located between the display panel and the first base substrate, the polarizing member transmitting light having a first polarization axis,
wherein light incident from the display panel to the first base substrate when a three-dimensional image is generated has the first polarization axis, and
wherein an angle formed by the long-axis direction of the liquid crystal molecules and a linear polarization direction by the first polarization axis is in a range of zero degrees to about 45 degrees.

19. The electronic device of claim 16, wherein a cross-sectional area of the liquid crystal molecules in a cross-section of the plurality of lenses taken in the longitudinal direction of the boundary decreases as the angle formed by the longitudinal direction of the boundary and the long-axis direction of the liquid crystal molecules decreases.

20. The electronic device of claim 18, wherein:
light incident from the display panel to the first base substrate has a second polarization axis when a two-dimensional image; and
the linear polarization direction by the first polarization axis forms an acute angle or an obtuse angle with a linear polarization direction by the second polarization axis.
